(19) United States
(12) Patent Application Publication
(10) Pub. No.: US 2025/0266097 A1
(43) Pub. Date: Aug. 21, 2025

(54) MEMORY DEVICE, MEMORY SYSTEM, AND ERASING METHOD OF THE MEMORY DEVICE

(71) Applicant: SAMSUNG ELECTRONICS CO., LTD., Suwon-si (KR)

(72) Inventors: Yohan Lee, Suwon-si (KR); Sojin Lee, Suwon-si (KR); Beomjin Park, Suwon-si (KR); Sangsoo Park, Suwon-si (KR); Jaeyun Lee, Suwon-si (KR)

(21) Appl. No.: 19/015,068

(22) Filed: Jan. 9, 2025

(30) Foreign Application Priority Data
Feb. 16, 2024 (KR) 10-2024-0022810

(51) Int. Cl. G11C 16/16; G11C 16/08; G11C 16/32

(52) U.S. Cl. CPC G11C 16/16; G11C 16/08; G11C 16/32

(57) ABSTRACT

A memory device includes a memory cell array including a plurality of cell strings each extending in a vertical direction on a substrate. A plurality of word lines include first word lines connected to memory cells relatively close to the ground erase control transistor and second word lines connected to memory cells relatively far from the ground erase control transistor and a row decoder configured to apply a first bias voltage to the first word lines and the dummy word lines in a first period of an erase setup period, and a second bias voltage at a level lower than a level of the first bias voltage to the first word lines and the dummy word line in a second period during the erase setup period. The second period starts before the level of the voltage applied to the common source line reaches the erase voltage level.

### CROSS-REFERENCE TO RELATED APPLICATION

This application claims priority under 35 U.S.C. § 119 to Korean Patent Application No. 10-2024-0022810, filed on Feb. 16, 2024, in the Korean Intellectual Property Office, the entirety of which is incorporated by reference herein.

### BACKGROUND

Memory devices are used to store data and are divided into volatile memory devices and non-volatile memory devices. In response to demand for high capacity and miniaturization of non-volatile memory devices, a three-dimensional memory device including a plurality of vertical channel structures extending in a vertical direction on a substrate has been developed.

### SUMMARY

Some aspects of this disclosure relate to memory devices including a memory cell string including a lower gate induced drain leakage (GIDL) transistor, in which a hot carrier injection (HCI) phenomenon may be prevented from occurring in the GIDL transistor during an erase operation.

According to some implementations of this disclosure, there is provided a memory device including a memory cell array including a plurality of cell strings each extending in a vertical direction on a substrate. Each cell string includes a plurality of memory cells respectively connected to a plurality of word lines, a ground erase control transistor connected to a ground erase control line, and at least one dummy memory cell connected to a dummy word line. The ground erase control transistor and the at least one dummy memory cell are connected between a common source line and the plurality of memory cells. The plurality of word lines include first word lines connected to memory cells relatively close to the ground erase control transistor and second word lines connected to memory cells relatively far from the ground erase control transistor and a row decoder configured to apply, during an erase operation on the memory cell array, a first bias voltage to the first word lines and the dummy word lines in a first period of an erase setup period, and a second bias voltage at a level lower than a level of the first bias voltage to the first word lines and the dummy word line in a second period after the first period during the erase setup period. The erase setup period is a period in which a level of a voltage applied to the common source line increases to an erase voltage level that is a target voltage level. The second period starts before the level of the voltage applied to the common source line reaches the erase voltage level.

According to some implementations of this disclosure, there is provided a memory system including a memory controller and a memory device configured to perform an erase operation in response to an erase command received from the memory controller. The memory device includes a memory cell array including a plurality of cell strings each extending in a vertical direction on a substrate, each cell string includes a plurality of memory cells respectively connected to a plurality of word lines, a ground erase control transistor connected to a ground erase control line, and at least one dummy memory cell connected to a dummy word line, the ground erase control transistor and the at least one dummy memory cell are connected between a common source line and the plurality of memory cells, and the plurality of word lines include first word lines connected to memory cells relatively close to the ground erase control transistor and second word lines connected to memory cells relatively far from the ground erase control transistor and a row decoder configured to apply, during an erase operation on the memory cell array, a first bias voltage to the first word lines and the dummy word lines in a first period of an erase setup period, and a second bias voltage at a level lower than a level of the first bias voltage to the first word lines and the dummy word line in a second period after the first period during the erase setup period. The erase setup period is a period in which a level of a voltage applied to the common source line increases to an erase voltage level that is a target voltage level, and the second period starts before the level of the voltage applied to the common source line reaches the erase voltage level.

According to some implementations of this disclosure, there is provided an erasing method of a memory device. The memory device includes a memory cell array including a plurality of cell strings each extending in a vertical direction on a substrate, each cell string includes a plurality of memory cells respectively connected to a plurality of word lines, a ground erase control transistor connected to a ground erase control line, and at least one dummy memory cell connected to a dummy word line, the ground erase control transistor and the at least one dummy memory cell are connected between a common source line and the plurality of memory cells, and the plurality of word lines include first word lines connected to memory cells relatively close to the ground erase control transistor and second word lines connected to memory cells relatively far from the ground erase control transistor, the erasing method includes applying a first bias voltage to the first word lines and the dummy word line in a first period of an erase setup period and applying a second bias voltage at a level lower than a level of the first bias voltage to the first word lines and the dummy word line in a second period after the first period in the erase setup period, the erase setup period is a period in which a level of a voltage applied to the common source line increases to an erase voltage level that is a target voltage level, and the second period starts before the level of the voltage applied to the common source line reaches the erase voltage level.

### BRIEF DESCRIPTION OF THE DRAWINGS

The foregoing and other implementations will be more clearly understood from the following detailed description taken in conjunction with the accompanying drawings in which:

FIG. 1 is a block diagram illustrating an example of a memory system;

FIG. 2 is a block diagram illustrating an example of a memory device;

FIGS. 3A, 3B, 3C, and 3D are circuit diagrams illustrating examples of memory blocks;

FIGS. 4A and 4B are perspective views illustrating examples of memory blocks;

FIG. 5A is a perspective view illustrating an example of a memory block;

FIG. 5B illustrates connection of a pass transistor circuit, a row decoder, and a cell string in an example of a memory block;

FIG. 6 is a timing diagram illustrating an example of an erase operation of a memory device;

FIG. 7 is a timing diagram illustrating an example of an erase operation of a memory device;

FIG. 8 is a flowchart illustrating an example of an erase method of a memory device;

FIG. 9 is a graph illustrating an example of channel potential for a distance from a common source line;

FIG. 10 is a flowchart illustrating an example of an operating method of a memory system;

FIG. 11 illustrates an example of a memory device having a cell over peri (COP) structure;

FIG. 12 is a cross-sectional view of an example of a memory device having a BVNAND structure; and

FIG. 13 is a block diagram illustrating an example in which a memory device is applied to a solid state drive (SSD) system.

### DETAILED DESCRIPTION

Hereinafter, various examples will be described in detail with reference to the accompanying drawings.

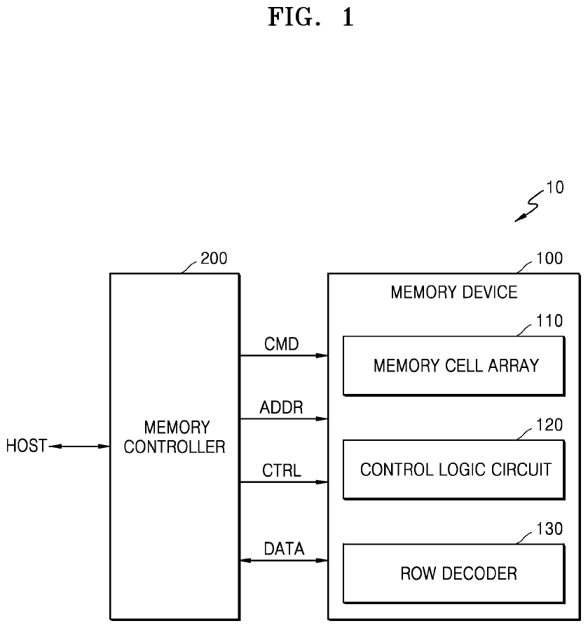

FIG. 1 is a block diagram illustrating a memory system 10 according to some implementations.

Referring to FIG. 1, the memory system 10 may include a memory device 100 and a memory controller 200, and the memory device 100 may include a memory cell array 110, a control logic circuit 120, and a row decoder 130. The memory device 100 may be a non-volatile memory device.

The memory controller 200 may control the memory device 100 to read data stored in the memory device 100 or to program data in the memory device 100 in response to a read/write request from a host HOST. For example, the memory controller 200 may control program, read, and erase operations of the memory device 100 by providing an address ADDR, a command CMD, and a control signal CTRL to the memory device 100. In addition, data DATA for programming and read data DATA may be transmitted and received between the memory controller 200 and the memory device 100.

The memory cell array 110 may include a plurality of memory cells. For example, the plurality of memory cells may be flash memory cells. Hereinafter, implementations will be described in detail by taking a case in which the plurality of memory cells are NAND flash memory cells, as an example. However, the present disclosure is not limited thereto. In some implementations, the plurality of memory cells are another type such as are resistive memory cells such as resistive random access memory (ReRAM), phase change RAM (PRAM), or magnetic RAM (MRAM).

The control logic circuit 120 may receive the command CMD, the address ADDR, and the control signal CTRL from the memory controller 200, and may control an overall operation of the memory device 100 based on the received command CMD, address ADDR, and control signal CTRL.

The row decoder 130 may apply voltages according to an operation mode to signal lines connected to the plurality of memory cells of the memory cell array 110, for example, a plurality of word lines, a string selection line, a ground selection line, an erase control line, and a common source line, under the control of the control logic circuit 120.

In some implementations, the memory device 100 performs an erase operation by a gate induced drain leakage (GIDL) method, and the control logic circuit 120 may control the row decoder 130 to output an erase voltage, an erase control voltage, and a bias voltage according to the GIDL method. The row decoder 130 may apply a first bias voltage to word lines and a dummy word line connected to memory cells relatively close to a ground erase control transistor in a first period of an erase setup period in which the erase voltage is set up. The row decoder 130 may apply a second bias voltage (for example, a ground voltage (for example, 0 V) or a voltage close to the ground voltage), at a level lower than a level of the first bias voltage, to the word lines and the dummy word line connected to the memory cells relatively close to the ground erase control transistor in a second period after the first period of the erase setup period.

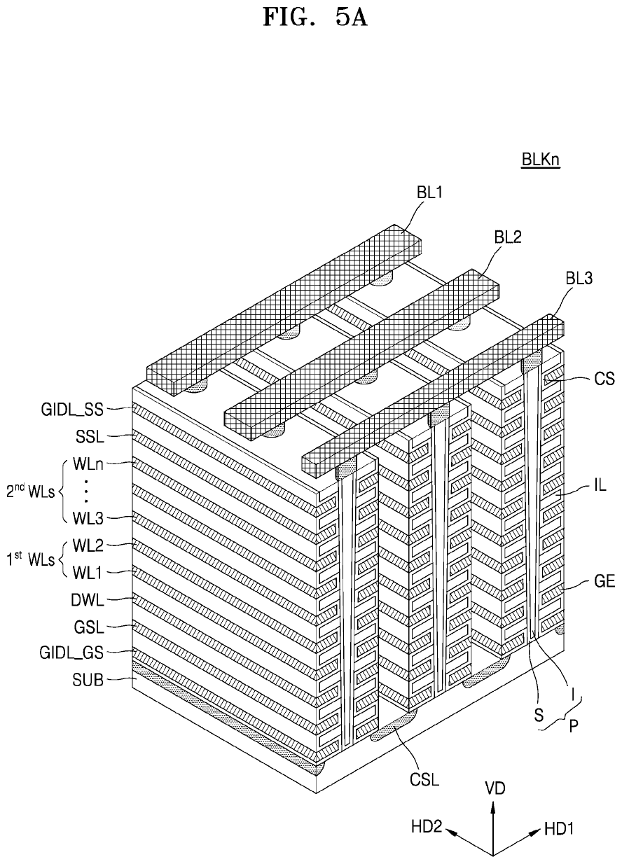

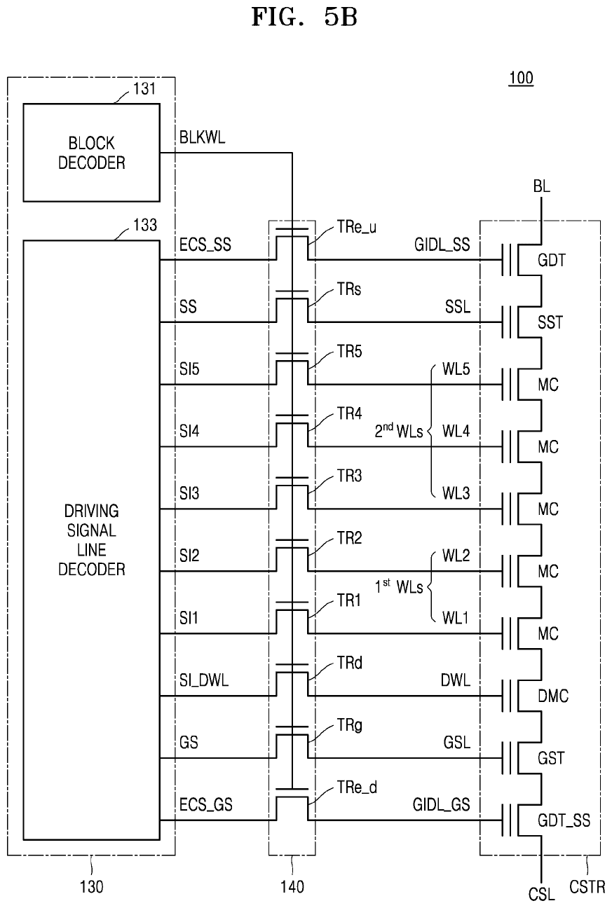

According to some implementations, by applying the bias voltage at the level higher than the level of the voltage applied to the common source line to the word lines and the dummy word line connected to the memory cells relatively close to the ground erase control transistor during the erase setup period, it is possible to reduce or prevent a hot carrier injection (HCI) phenomenon that may occur before holes are injected into a channel (e.g., before a GIDL current is generated) from occurring, which will be described in detail with reference to FIGS. 5A to 9.

In some implementations, the memory system 10 is internal memory built into an electronic device. The memory system 10 may be, for example, a solid state drive (SSD), a memory card, a micro secure digital (SD) card, or an embedded multi-media card (eMMC). In some implementations, the memory system 10 is external memory that is removable from the electronic device. For example, the memory system 10 may be a universal flash storage (UFS) memory card, compact flash (CF), secure digital (SD), micro secure digital (micro-SD), mini secure digital (mini-SD), extreme digital (xD), or memory stick.

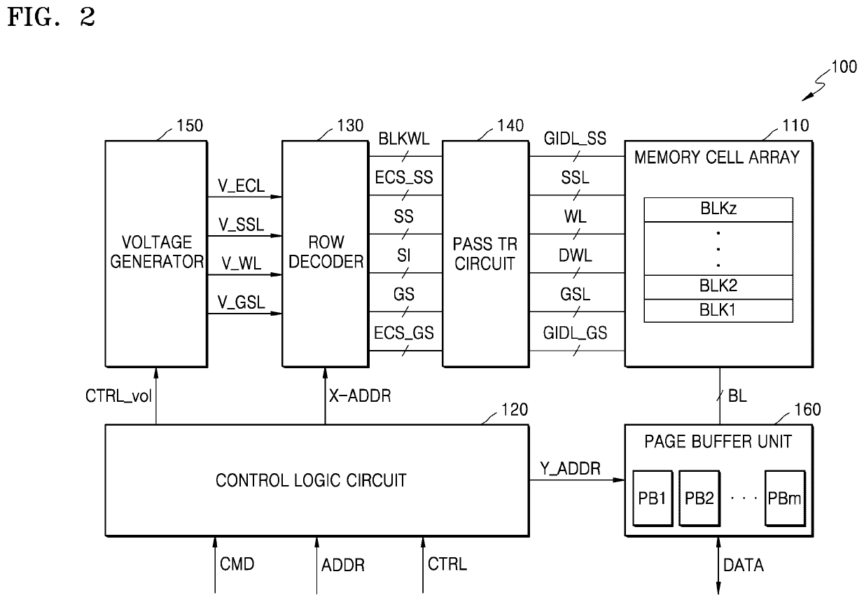

FIG. 2 is a block diagram illustrating a memory device 100 according to some implementations of the present disclosure.

Referring to FIG. 2, the memory device 100 includes a memory cell array 110, a control logic circuit 120, a row decoder 130, a pass transistor circuit 140, a voltage generator 150, and a page buffer circuit 160. The memory device 100 may further include an interface circuit, and the interface circuit may include a data input/output circuit and a command/address input/output circuit.

The memory cell array 110 may include a plurality of memory blocks BLK1 to BLKz, where z is a positive integer. Each of the plurality of memory blocks BLK1 to BLKz may include a plurality of pages, and each of the plurality of pages may include a plurality of memory cells. For example, a memory block may be a unit of erase, and a page may be a unit of writing and reading. Each memory cell may store one or more bits. For example, each memory cell may be used as a single level cell (SLC), a multi-level cell (MLC), a triple level cell (TLC), or a quadruple level cell (QLC).

In addition, each of the plurality of memory blocks BLK1 to BLKz may include at least one dummy memory cell, and a dummy word line may be connected to a gate of the dummy memory cell. The dummy memory cell may have the same structure as the memory cell. However, the dummy memory cell does not perform program and read operations, unlike the memory cell. For example, the dummy memory cell is not used as a data storage device.

In addition, the memory cell array 110 may be connected to erase control lines GIDL_SS, a plurality of string selection lines SSL, a plurality of word lines WL, a plurality of dummy word lines DWL, a plurality of ground selection lines GSL, lower erase control lines GIDL_GS, and a plurality of bit lines BL. The memory cell array 110 may be connected to the pass transistor circuit 140 through the erase control lines GIDL_SS, the plurality of string selection lines SSL, the plurality of word lines WL, the plurality of dummy word lines DWL, the plurality of ground selection lines GSL, and the lower erase control lines GIDL_GS, and may be connected to the page buffer circuit 160 through the plurality of bit lines BL.

In some implementations, the memory cell array 110 includes a 3D memory cell array, and the 3D memory cell array may include a plurality of NAND strings. Each NAND string may include memory cells respectively connected to word lines vertically stacked on a substrate. For example, the memory cell array 110 may have a structure as described in U.S. Pat. Nos. 7,679,133, 8,553,466, 8,654,587, 8,559,235, and/or U.S. Patent Application Publication No. 2011/0233648.

The control logic circuit 120 may write data to the memory cell array 110 and may output various control signals for reading data from the memory cell array 110 based on a command CMD, an address ADDR, and a control signal CTRL received from a memory controller 200. Accordingly, the control logic circuit 120 may generally control various operations in the memory device 100. For example, the control logic circuit 120 may provide a voltage control signal CTRL_vol to the voltage generator 150, may provide a row address X_ADDR to the row decoder 130, and may provide a column address Y_ADDR to the page buffer circuit 160. However, the operations are not limited thereto, and the control logic circuit 120 may further provide other control signals to the voltage generator 150, the row decoder 130, and the page buffer circuit 160.

The voltage generator 150 may generate various types of voltages for performing program, read, and erase operations based on the voltage control signal CTRL_vol. For example, the voltage generator 150 may generate an erase control line voltage V_ECL, a word line voltage V_WL, a string selection line voltage V_SSL, and a ground selection line voltage V_GSL, and may provide the generated erase control line voltage V_ECL, word line voltage V_WL, string selection line voltage V_SSL, and ground selection line voltage V_GSL to the row decoder 130.

For example, the voltage generator 150 may generate a plurality of erase control voltages including a first erase control voltage and a second erase control voltage as the erase control line voltage V_ECL. For example, the voltage generator 150 may generate a program voltage, a read voltage, a program verification voltage, and an erase voltage as the word line voltage V_WL. For example, the voltage generator 150 may generate a selection voltage and a non-selection voltage as the string selection line voltage V_SSL. For example, the voltage generator 150 may generate the selection voltage and the non-selection voltage as the ground selection line voltage V_GSL. In addition, when the memory device 100 performs an erase operation by the GIDL method, the voltage generator 150 may further generate a voltage applied to a bit line or a voltage applied to a common source line.

During the erase operation, the row decoder 130 may provide an erase voltage to pass transistors (for example, TR1 to TR5 of FIG. 5B) included in the pass transistor circuit 140 through a plurality of word line driving signal lines SI in response to the row address X_ADDR. In addition, the row decoder 130 may provide erase control voltages to pass transistors included in the pass transistor circuit 140 through a plurality of erase control line driving signal lines during the erase operation. For example, the row decoder 130 may provide an erase control voltage to the pass transistor (for example, TRe_d of FIG. 5B) through a lower erase control line driving signal line ECS_GS, and may provide an erase control voltage to the pass transistor (for example, TRe_u of FIG. 5B) through an upper erase control line driving signal line ECS_SS. Furthermore, during the erase operation, the row decoder 130 may provide a bias voltage to pass transistors (for example, TRs and TRg of FIG. 5B) included in the pass transistor circuit 140 through string selection line driving signal lines SS and ground selection line driving signal lines GS.

In some implementations, the memory device 100 performs the erase operation by the GIDL method, and the control logic circuit 120 controls the row decoder 130 to output the erase voltage, the erase control voltage, and the bias voltage according to the GIDL method. The row decoder 130 may apply the first bias voltage to the word lines and the dummy word line connected to the memory cells relatively close to the ground erase control transistor in the first period of the erase setup period in which the erase voltage is set up. The row decoder 130 may apply the second bias voltage (for example, the ground voltage (for example, 0 V) or the voltage close to the ground voltage), at the level lower than the level of the first bias voltage, to the word lines and the dummy word line connected to the memory cells relatively close to the ground erase control transistor in the second period after the first period of the erase setup period.

According to some implementations, by applying the bias voltage at the level higher than the level of the voltage applied to the common source line to the word lines and the dummy word line connected to the memory cells relatively close to the ground erase control transistor during the erase setup period, it is possible to reduce or prevent a hot carrier injection (HCI) phenomenon that may occur before holes are injected into a channel (that is, before a GIDL current is generated) from occurring, which will be described in detail with reference to FIGS. 5A to 9.

The page buffer circuit 160 may select at least one bit line among the plurality of bit lines BL based on the column address Y_ADDR. The page buffer circuit 160 may operate as a write driver or a sense amplifier according to an operation mode. The page buffer circuit 160 may include a plurality of page buffers PB1 to PBm and m is a positive integer. For example, m may correspond to the number of bit lines BL, and the plurality of page buffers PB1 to PBm may be connected to the plurality of bit lines BL, respectively. For example, the plurality of bit lines BL may be grouped into a plurality of bit line groups, and bit lines included in each of the plurality of bit line groups may share a page buffer.

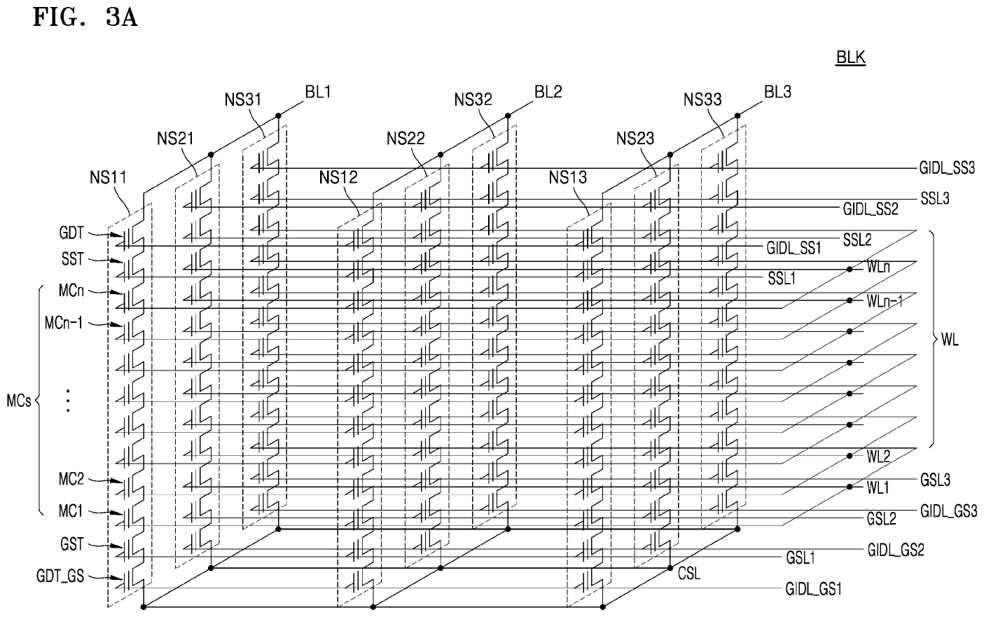

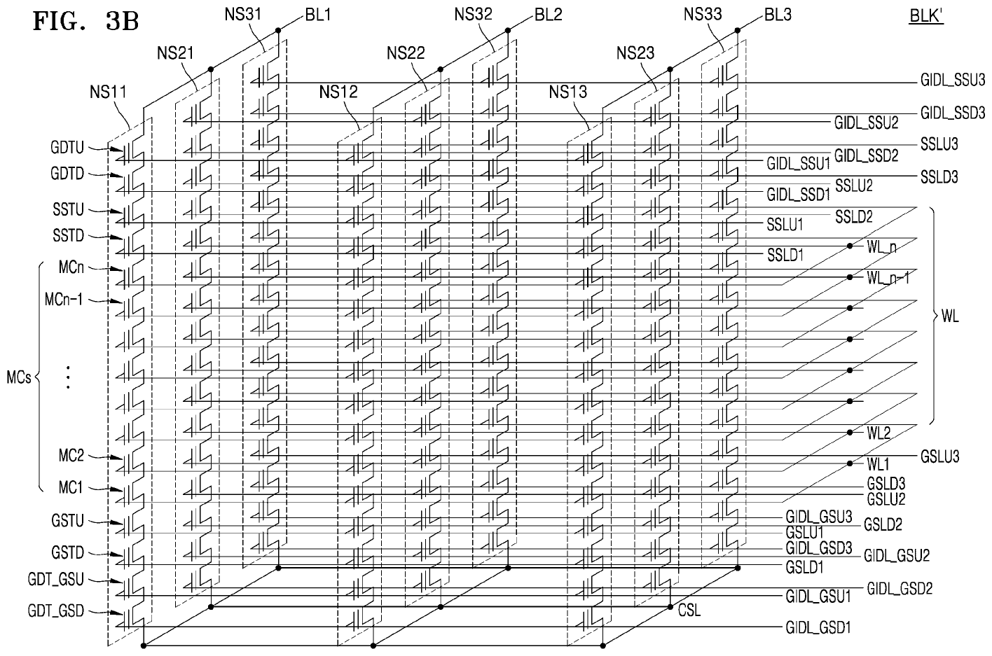

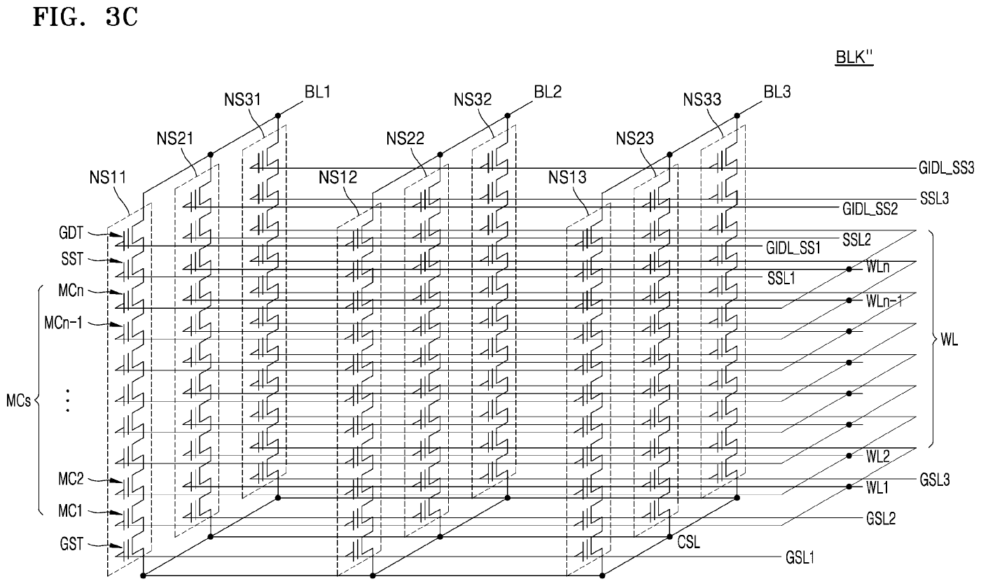

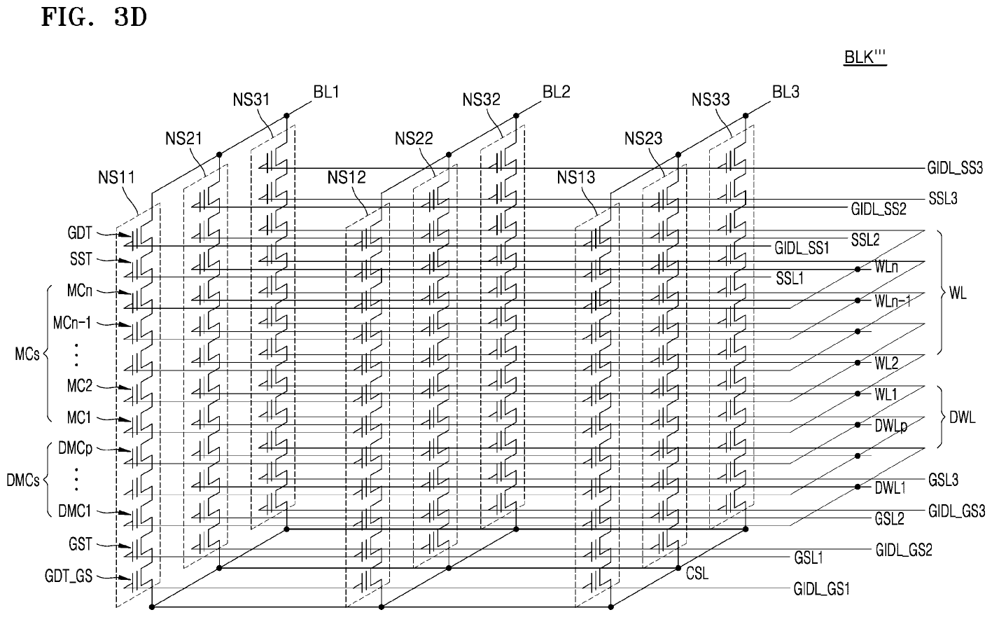

FIGS. 3A, 3B, 3C, and 3D are circuit diagrams illustrating examples of memory blocks, e.g., memory blocks BLK of the memory cell array 110.

Referring to FIG. 3A, the memory block BLK may correspond to one of the plurality of memory blocks BLK1 to BLKz of FIG. 2. The memory block BLK may be connected to first to third bit lines BL1 to BL3, first to third erase control lines GIDL_SS1 to GIDL_SS3, string selection lines SSL1 to SSL3, word lines WL, ground selection lines GSL1 to GSL3, and erase control lines GIDL_GS1 to GIDL_GS3, and may include NAND strings or cell strings NS11 to NS33 extending in a vertical direction VD. Here, the number of cell strings, the number of word lines, the number of bit lines, the number of ground selection lines, the number of string selection lines, and the number of erase control lines may vary in various implementations.

The first to third bit lines BL1 to BL3 may extend in a first direction or a first horizontal direction HD1, and the word lines WL1 to WLn may extend in a second direction or a second horizontal direction HD2, where n is a positive integer. The NAND strings NS11, NS21, and NS31 may be positioned between the first bit line BL1 and a common source line CSL, the NAND strings NS12, NS22, and NS32 may be positioned between the second bit line BL2 and the common source line CSL, and the NAND strings NS13, NS23, and NS33 may be positioned between the third bit line BL3 and the common source line CSL.

For example, the NAND string NS11 may include an erase control transistor GDT, a string selection transistor SST, a plurality of memory cells MCs, a ground selection transistor GST, and an erase control transistor GDT_GS that are serially connected to one another. The erase control transistor GDT may be connected to the corresponding first bit line BL1 and the corresponding first erase control line GIDL_SS1. The string selection transistor SST may be connected to the corresponding string selection line SSL1, and the plurality of memory cells MCs may be connected to the corresponding word lines WL1 to WLn, respectively.

The ground selection transistor GST may be connected to the corresponding ground selection line GSL1. The erase control transistor GDT_GS may be connected to the corresponding erase control line GIDL_GS1 and the common source line CSL. Hereinafter, the erase control lines GIDL_GS1 to GIDL_GS3 arranged below the ground selection lines GSL1 to GSL3 are referred to as “ground erase control lines,” and the erase control transistor GDT_GS is referred to as a “ground erase control transistor.” Here, the erase control transistor GDT_GS may be referred to as a lower GIDL transistor.

Referring to FIG. 3B, the memory block BLK′ may correspond to one of the plurality of memory blocks BLK1 to BLKz of FIG. 2. The memory block BLK′ corresponds to a modified example of the memory block BLK of FIG. 3A, and hereinafter, differences from the memory block BLK of FIG. 3A will be mainly described. The memory block BLK′ may be connected to bit lines BL1 to BL3, upper erase control lines GIDL_SSU1 to GIDL_SSU3, lower erase control lines GIDL_SSD1 to GIDL_SSD3, upper string selection lines SSLU1 to SSLU3, lower string selection lines SSLD1 to SSLD3, word lines WL, upper ground selection lines GSLU1 to GSLU3, lower ground selection lines GSLD1 to GSLD3, upper ground erase control lines GIDL_GSU1 to GIDL_GSU3, and lower ground erase control lines GIDL_GSD1 to GIDL_GSD3, and may include cell strings NS11 to NS33 extending in the vertical direction VD.

For example, the cell string NS11 may include an upper erase control transistor GDTU, a lower erase control transistor GDTD, an upper string selection transistor SSTU, a lower string selection transistor SSTD, a plurality of memory cells MCs, an upper ground selection transistor GSTU, a lower ground selection transistor GSTD, an upper ground erase control transistor GDT_GSU, and a lower ground erase control transistor GDT_GSD that are serially connected to one another. The upper erase control transistor GDTU may be connected to the corresponding bit line BL1 and the corresponding upper erase control line GIDL_SSU1, and the lower erase control transistor GDTD may be connected to the corresponding lower erase control line GIDL_SSD1.

The upper string selection transistor SSTU may be connected to the corresponding upper string selection line SSLU1, and the lower string selection transistor SSTD may be connected to the corresponding lower string selection line SSLD1. The upper ground selection transistor GSTU may be connected to the corresponding upper ground selection line GSLU1, and the lower ground selection transistor GSTD may be connected to the corresponding lower ground selection line GSLD1. The upper ground erase control transistor GDT_GSU may be connected to the corresponding upper ground erase control line GIDL_GSU1, and the lower ground erase control transistor GDT_GSD may be connected to the corresponding lower ground erase control line GIDL_GSD1 and a common source line CSL.

Referring to FIG. 3C, the memory block BLK″ may correspond to one of the plurality of memory blocks BLK1 to BLKz of FIG. 2. The memory block BLK″ corresponds to a modified example of the memory block BLK of FIG. 3A, and hereinafter, differences from the memory block BLK of FIG. 3A will be mainly described.

The memory block BLK″ may be connected to first to third bit lines BL1 to BL3, first to third erase control lines GIDL_SS1 to GIDL_SS3, string selection lines SSL1 to SSL3, word lines WL, and ground selection lines GSL1 to GSL3, and may include cell strings NS11 to NS33 extending in the vertical direction VD. Compared with the memory block BLK of FIG. 3A, the memory block BLK″ may not include a ground erase control line GIDL_GS, and each cell string may not include a ground erase control transistor GDT_GS.

Referring to FIG. 3D, the memory block BLK″ may correspond to one of the plurality of memory blocks BLK1 to BLKz of FIG. 2. The memory block BLK″ corresponds to a modified example of the memory block BLK of FIG. 3A, and hereinafter, differences from the memory block BLK of FIG. 3A will be mainly described.

The memory block BLK″ may be connected to first to third bit lines BL1 to BL3, first to third erase control lines GIDL_SS1 to GIDL_SS3, string selection lines SSL1 to SSL3, word lines WL, and ground selection lines GSL1 to GSL3, and may include cell strings NS11 to NS33 extending in the vertical direction VD. Compared with the memory block BLK of FIG. 3A, the memory block BLK″′ may be connected to a dummy word line DWL, and each of the cell strings NS11 to NS33 may include at least one dummy memory cell.

For example, the NAND string NS11 may further include a plurality of dummy memory cells DMCs serially connected to a plurality of memory cells MCs, respectively. The plurality of dummy memory cells DMCs may be connected to corresponding dummy word lines DWL1 to DWLp, respectively. The dummy word lines DWL1 to DWLp may extend in the second direction or the second horizontal direction HD2. P is a positive integer. In addition, the plurality of dummy memory cells DMCs may be positioned between the plurality of memory cells MCs and a ground selection transistor GST.

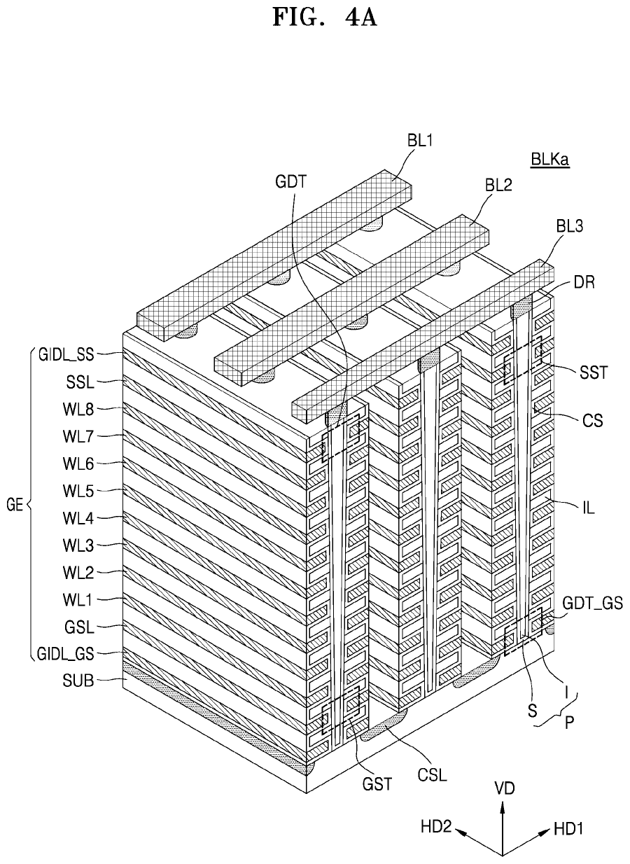

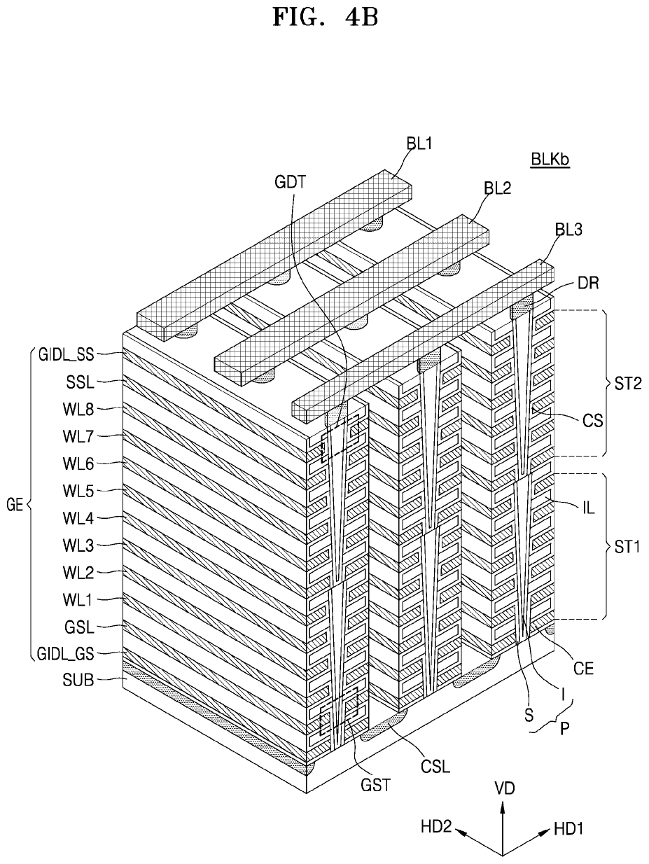

FIG. 4A is a perspective view illustrating a memory block BLKa according to some implementations.

Referring to FIG. 4A, the memory block BLKa may correspond to one of the plurality of memory blocks BLK1 to BLKz of FIG. 2. The memory block BLKa is formed in the vertical direction VD with respect to a substrate SUB. The substrate SUB has a first conductivity type (for example, p-type) and extends in the second horizontal direction HD2 on the substrate SUB. In some implementations, a common source line CSL doped with impurities of a second conductivity type (for example, n-type) is provided on the substrate SUB. In some implementations, the substrate SUB includes polysilicon, and a plate-shaped common source line CSL may be arranged on the substrate SUB. A plurality of insulating layers IL extending in the second horizontal direction HD2 are sequentially provided on the substrate SUB in the vertical direction VD, and the plurality of insulating layers ILs are spaced apart by a specific distance in the vertical direction VD. For example, the plurality of insulating layers IL may include an insulating material such as silicon oxide.

A plurality of pillars P sequentially arranged in the first horizontal direction HD1 and passing through the plurality of insulating layers IL in the vertical direction VD are provided on the substrate SUB. For example, the plurality of pillars P may contact the substrate SUB through the plurality of insulating layers IL. For example, a surface layer S of each pillar P may include a silicon material having the first conductivity type, and may function as a channel region. Accordingly, in some implementations, the pillar P may be referred to as a channel structure or a vertical channel structure. An internal layer I of each pillar P may include an insulating material such as silicon oxide or an air gap.

A charge storage layer CS is provided along exposed surfaces of the insulating layers IL, the pillars P, and the substrate SUB. The charge storage layer CS may include a gate insulating layer (sometimes referred to as a “tunneling insulating layer”), a charge trap layer, and a blocking insulating layer. For example, the charge storage layer CS may have an oxide-nitride-oxide (ONO) structure. In addition, gate electrodes GE such as a ground erase control line GIDL_GS, a ground selection line GSL, word lines WL1 to WL8, a string selection line SSL, and an erase control line GIDL_SS are provided on an exposed surface of the charge storage layer CS. The number of ground erase control lines GIDL_GS, ground selection lines GSL, word lines WL1 to WL8, string selection lines SSL, and erase control lines GIDL_SS may vary in various implementations.

Drain contacts or drains DR are provided on the plurality of pillars P, respectively. For example, the drains DR may include a silicon material doped with impurities having the second conductivity type. Bit lines BL1 to BL3 extending in the first horizontal direction HD1 and spaced apart by a specific distance in the second horizontal direction HD2 are provided on the drains DR.

An erase control transistor GDT may be positioned at an upper end of the memory block BLKa, and a ground erase control transistor GDT_GS may be positioned at a lower end of the memory block BLKa. For example, the erase control transistor GDT may be positioned between the bit lines BL1 to BL3 and a string selection transistor SST, and the ground erase control transistor GDT_GS may be positioned between a ground selection transistor GST and the substrate SUB.

Because the ground erase control transistor GDT_GS is adjacent to the lowermost end of the 3D memory cell array (for example, the substrate SUB including the common source line CSL), concentration of n-type conductive impurities may not be sufficiently controlled during the process. Accordingly, GIDL current generation characteristics of the ground erase control transistor GDT_GS may be inferior to those of the erase control transistor GDT adjacent to the bit line, and the ground erase control transistor GDT_GS may be vulnerable to the HCI phenomenon.

According to some implementations, by applying the bias voltage at the level higher than the level of the voltage applied to the common source line to the word lines and the dummy word line connected to the memory cells relatively close to the ground erase control transistor during the erase setup period, it is possible to reduce or prevent a hot carrier injection (HCI) phenomenon that may occur before holes are injected into a channel (that is, before a GIDL current is generated) from occurring, which will be described in detail with reference to FIGS. 5A to 9.

FIG. 4B is a perspective view illustrating a memory block BLKb according to some implementations.

Referring to FIG. 4B, the memory block BLKb may correspond to one of the plurality of memory blocks BLK1 to BLKz of FIG. 2. In addition, the memory block BLKb corresponds to a modified example of the memory block BLKa of FIG. 4A, and the content described in detail with reference to FIG. 4A may also be applied to FIG. 4B, except where noted otherwise or suggested otherwise by context. The memory block BLKb is formed in a direction perpendicular to the substrate SUB. The memory block BLKb may include a first memory stack ST1 and a second memory stack ST2 stacked in the vertical direction VD. However, the number of memory stacks is not limited thereto, and the memory block BLKb may include three or more memory stacks.

FIG. 5A is a perspective view illustrating a memory block BLKn according to some implementations.

Referring to FIG. 5A, the memory block BLKn may correspond to one of the plurality of memory blocks BLK1 to BLKz of FIG. 2, for example, BLK″′ of FIG. 3D In addition, the memory block BLKn corresponds to a modified example of the memory block BLKa of FIG. 4A, and the content described in detail with reference to FIG. 4A may also be applied to FIG. 5A, except where noted otherwise or suggested otherwise by context.

Gate electrodes GE such as a ground erase control line GIDL_GS, a ground selection line GSL, a dummy word line DWL, word lines WL1 to WL5, a string selection line SSL, and an erase control line GIDL_SS are provided on an exposed surface of a charge storage layer CS. In addition, in FIG. 5A, one dummy word line DWL is shown, but the number of dummy word lines is not limited thereto, and the dummy word line DWL may be implemented with a plurality of dummy word lines.

Hereinafter, word lines connected to the memory cells relatively close to the ground erase control transistor GDT_GS are referred to as first word lines 1st WLs, and word lines connected to memory cells relatively far from the ground erase control transistor GDT_GS may be referred to as second word lines 2nd WLs.

For example, the first word lines 1st WLs may include k word lines in order closest to the ground erase control transistor GDT_GS, and the second word lines 2nd WLs may include word lines excluding the first word lines 1st WLs among the plurality of word lines. k is a positive integer.

For example, referring to FIG. 5A, the first word lines 1st WLs may include two word lines including a word line WL1 and a word line WL2, and the second word lines 2nd WLs may include word lines WL3 to WLn excluding the word line WL1 and the word line WL2 among the n word lines WL1 to WLn. n is a positive integer.

FIG. 5B illustrates connections of a pass transistor circuit 140, a row decoder 130, and a cell string CSTR included in a memory block BLKn according to some implementations.

Referring to FIG. 5B, the memory device 100 may include the cell string CSTR, the pass transistor circuit 140, and the row decoder 130, and the row decoder 130 may include a block decoder 131 and a driving signal line decoder 133. Here, the cell string CSTR may correspond to one of a plurality of cell strings included in the memory block BLKn described in FIG. 5A. Hereinafter, for convenience of description, it is assumed that n is 5 and k is 2.

The pass transistor circuit 140 may include a plurality of pass transistors TRe_u, TRs, TR1 to TR5, TRd, TRg, and TRe_d. The block decoder 131 may be connected to the pass transistor circuit 140 through a block word line BLKWL. The block word line BLKWL may be connected to gates of the plurality of pass transistors TRe_u, TRs, TR1 to TR5, TRd, TRg, and TRe_d. For example, when a block selection signal provided through the block word line BLKWL is activated, the plurality of pass transistors TRe_u, TRs, TR1 to TR5, TRd, TRg, and TRe_d are turned on, and accordingly, a memory block may be selected.

The driving signal line decoder 133 (e.g., a circuit) may be connected to the pass transistor circuit 140 through a ground erase control line driving signal line ECS_GS, a ground selection line driving signal line GS, a dummy word line driving signal line SI_DWL, word line driving signal lines SI1 to SI5, a string selection line driving signal line SS, and erase control line driving signal lines ECS_SS. For example, the ground erase control line driving signal line ECS_GS, the ground selection line driving signal line GS, the dummy word line driving signal line SI_DWL, the word line driving signal lines SI1 to SI5, the string selection line driving signal line SS, and first and second erase control line driving signal lines ECSa and ECSb may be connected to sources of the plurality of pass transistors TRe_u, TRs, TR1 to TR5, TRd, TRg, and TRe_d, respectively.

The pass transistor circuit 140 may be connected to the cell string CSTR included in the memory block through a ground erase control line GIDL_GS, a ground selection line GSL, a dummy word line DWL, word lines WL1 to WL5, a string selection line SSL, and an erase control line GIDL_SS. For example, the ground erase control line GIDL_GS, the ground selection line GSL, the dummy word line DWL, the word lines WL1 to WL5, the string selection line SSL, and the erase control line GIDL_SS may be connected to drains of the plurality of pass transistors TRe_u, TRs, TRs, TR1 to TR5, TRd, TRg, and TRe_d, respectively.

The pass transistor TRe_d may be connected between the ground erase control line driving signal line ECS_GS and the ground erase control line GIDL_GS. The pass transistor TRg may be connected between the ground selection line driving signal line GS and the ground selection line GSL. The pass transistor TRd may be connected between the dummy word line driving signal line SI_DWL and the dummy word line DWL. Pass transistors TR1 to TRn may be connected between word line driving signal lines SI1 to SIn and a plurality of word lines WL1 to WLn, respectively. The pass transistor TRs may be connected between the string selection line driving signal line SS and the string selection line SSL. The pass transistor TRe_u may be connected between the erase control line driving signal line ECS_SS and the erase control line GIDL_SS.

For example, when the block selection signal is activated, the plurality of pass transistors TRe_u, TRs, TR1 to TR5, TRd, TRg, and TRe_d may provide driving signals provided through the ground erase control line driving signal line ECS_GS, the ground selection line driving signal line GS, the dummy word line driving signal line SI_DWL, the word line driving signal lines SI1 to SI5, the string selection line driving signal line SS, and the erase control line driving signal line ECS_SS to the ground erase control line GIDL_GS, the ground selection line GSL, the dummy word line DWL, the word lines WL1 to WL5, the string selection line SSL, and the erase control line GIDL_SS.

In addition, it is illustrated in FIG. 5B that one pass transistor TRd is connected to the dummy word line driving signal line SI_DWL and the dummy word line DWL. However, number of pass transistors TRd is not limited thereto, and the pass transistor TRd may be implemented in plural numbers equal to the number of dummy memory cells DMC included in one cell string CSTR. In addition, each of the dummy word line driving signal line SI_DWL and the dummy word line DWL may be implemented in plural numbers equal to the number of dummy memory cells DMC included in one cell string CSTR.

The erase operation may be an erase operation for the memory block BLKn of FIG. 5A, and may be referred to as a “GIDL erase operation.”

According to some implementations, the GIDL erase operation may include a lower GIDL erase operation in which an erase voltage V_ERS is injected into a common source line through the control of a voltage applied to the common source line, an upper GIDL erase operation in which the erase voltage V_ERS is injected into a bit line through the control of a voltage applied to the bit line, and a bidirectional GIDL erase operation in which the erase voltage V_ERS is injected into the common source line and the bit line through the control of a voltage applied to each of the common source line and the bit line.

Hereinafter, examples of the lower GIDL erase operation will be described.

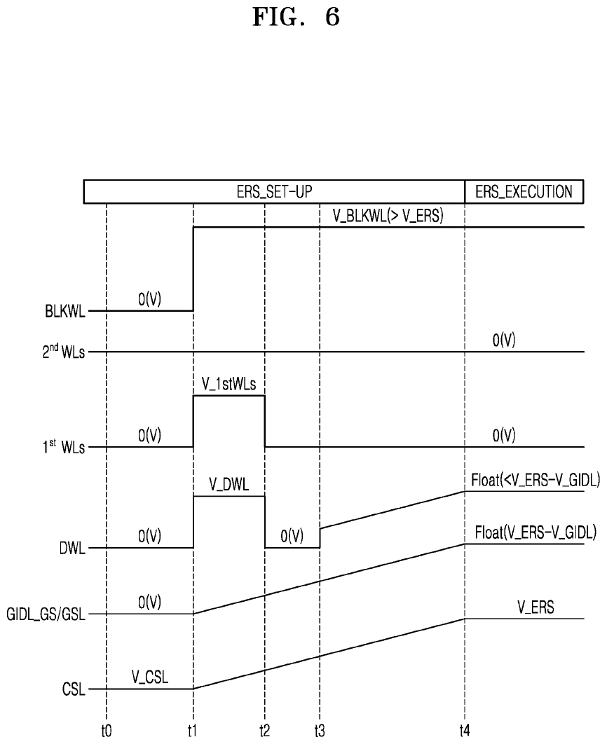

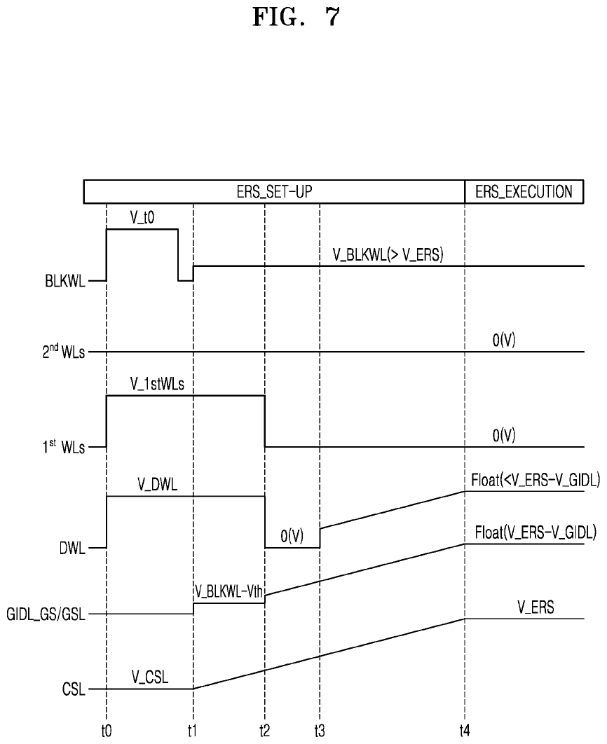

Specifically, a case in which the level of the voltage V_BLKWL applied to the block word line BLKWL is higher than the level of the erase voltage V_ERS in the erase execution period ERS_EXECUTION of the lower GIDL erase operation will be described with reference to FIG. 6, and a case in which the level of the voltage V_BLKWL applied to the block word line BLKWL is lower than the level of the erase voltage V_ERS in the erase execution period ERS_EXECUTION of the lower GIDL erase operation will be described with reference to FIG. 7.

FIG. 6 is a timing diagram illustrating an erase operation of a memory device. The erase operation according to the timing diagram of FIG. 6 may be performed by the memory device 100 of FIG. 1.

Referring to FIG. 6, a lower GIDL erase operation may be performed during a lower GIDL erase period including an erase setup period ERS_SET-UP and an erase execution period ERS_EXECUTION. For example, the erase operation may be the lower GIDL erase operation for the memory block BLKn of FIG. 5A.

In addition, in FIG. 6, description will be made assuming that a level of a voltage V_BLKWL applied to the block word line BLKWL is higher than a level of an erase voltage V_ERS in the erase execution period ERS_EXECUTION of the lower GIDL erase operation.

In the erase setup period ERS_SET-UP, the memory device 100 may set a level of a voltage applied to the common source line CSL from a level of a ground voltage (for example, 0 V) or a voltage V_CSL close to the ground voltage to a level of the erase voltage V_ERS. For example, in the erase setup period ERS_SET-UP, the common source line CSL is selected as a transmission path of the erase voltage V_ERS and the level of the voltage applied to the common source line CSL increases to the level of the erase voltage V_ERS, which is a target voltage level.

For example, the memory device 100 may apply the ground voltage (for example, 0 V) or the voltage V_CSL close to the ground voltage to the common source line CSL from a 0th time point t0 to a first time point t1. The memory device 100 may increase the voltage applied to the common source line CSL with a predetermined slope from the first time point t1 to a fourth time point t4. For example, the voltage applied to the common source line CSL at the fourth time point t4 may reach the level of the erase voltage V_ERS. In some implementations, the memory device 100 steps up the voltage applied to the common source line CSL from the first time point t1 to the fourth time point t4, and the voltage applied to the common source line CSL at the fourth time point t4 may reach the level of the erase voltage V_ERS.

In the erase setup period ERS_SET-UP, the memory device 100 may make a voltage applied to the ground selection line GSL and the lower erase control line GIDL_GS floating at the ground voltage (for example, 0 V) or the voltage close to the ground voltage. Here, the voltage applied to the ground selection line GSL and the lower erase control line GIDL_GS may be coupled to the common source line CSL. For example, a level of the voltage applied to the ground selection line GSL and the lower erase control line GIDL_GS may be coupled to the level of the voltage applied to the common source line CSL and increase.

For example, the memory device 100 may apply the ground voltage (for example, 0 V) or the voltage V_CSL close to the ground voltage to the ground selection line GSL and the lower erase control line GIDL_GS from the 0th time point t0 to the first time point t1. The memory device 100 may make the ground selection line GSL and the lower erase control line GIDL_GS floating from the first time point t1 to the fourth time point t4. At the fourth time point t4, the ground selection line GSL and the lower erase control line GIDL_GS may have a floating voltage at a level at which a GIDL voltage V_GIDL is subtracted from the erase voltage V_ERS. Here, the GIDL voltage V_GIDL is generated by GIDL of the ground erase control transistor GDT_GS, and the ground erase control transistor GDT_GS may intentionally generate the GIDL during the erase operation.

In the erase setup period ERS_SET-UP, the memory device 100 may apply a bias voltage V_DWL to the dummy word line DWL, and may stop applying the bias voltage V_DWL to the dummy word line DWL before the level of the voltage applied to the common source line CSL reaches the level of the erase voltage V_ERS. Thereafter, the memory device 100 may apply the ground voltage (for example, 0 V) or the voltage close to the ground voltage to the dummy word line DWL, and may make the dummy word line DWL floating after a predetermined time has passed.

For example, the memory device 100 may apply the ground voltage (for example, 0 V) or the voltage close to the ground voltage to the dummy word line DWL from the 0th time point t0 to the first time point t1. The memory device 100 may apply the bias voltage V_DWL to the dummy word line DWL from the first time point t1 to a second time point t2. The memory device 100 may apply the ground voltage (for example, 0 V) or the voltage close to the ground voltage to the dummy word line DWL from the second time point t2 to a third time point t3. The memory device 100 may make the dummy word line DWL floating from the third time point t3 to the fourth time point t4. At the fourth time point t4, the dummy word line DWL may have a floating voltage at a level lower than the level at which the GIDL voltage V_GIDL is subtracted from the erase voltage V_ERS.

In the erase setup period ERS_SET-UP, the memory device 100 may apply a bias voltage V_1stWL to the first word lines 1st WLs, and may stop applying the bias voltage V_1stWL to the first word lines 1stWLs before the level of the voltage applied to the common source line CSL reaches the level of the erase voltage V_ERS.

For example, the memory device 100 may apply the ground voltage (for example, 0 V) or the voltage close to the ground voltage to the first word lines 1st WLs from the 0th time point t0 to the first time point t1. The memory device 100 may apply the bias voltage V_1stWL to the first word lines 1st WLs from the first time point t1 to the second time point t2. The memory device 100 may apply the ground voltage (for example, 0 V) or the voltage close to the ground voltage to the dummy word line DWL from the second time point t2 to the fourth time point t4.

In the erase setup period ERS_SET-UP, the memory device 100 may apply the ground voltage (for example, 0 V) or the voltage close to the ground voltage to the second word lines 2nd WLs.

For example, the memory device 100 may apply the ground voltage (for example, 0 V) or the voltage close to the ground voltage to the second word lines 2nd WLs from the 0th time point t0 to the fourth time point t4.

In the erase setup period ERS_SET-UP, the memory device 100 may apply the block word line voltage V_BLKWL at a level higher than the level of the erase voltage V_ERS to the block word line BLKWL.

For example, the memory device 100 may apply the ground voltage (for example, 0 V) or the voltage close to the ground voltage to the block word line BLKWL from the 0th time point t0 to the first time point t1. The memory device 100 may apply the block word line voltage V_BLKWL at the level higher than the level of the erase voltage V_ERS to the block word line BLKWL from the first time point t1 to the fourth time point t4.

In the erase execution period ERS_EXECUTION, the memory device 100 may maintain the level of the voltage applied to the common source line CSL as the level of the erase voltage V_ERS. For example, after the fourth time point t4, the common source line CSL may be maintained at the level of the erase voltage V_ERS. In the erase execution period ERS_EXECUTION, the memory device 100 may still make the dummy word line DWL floating. For example, after the fourth time point t4, the voltage of the dummy word line DWL may be maintained as the floating voltage at the level lower than the level at which the GIDL voltage V_GIDL is subtracted from the erase voltage V_ERS. In the erase execution period ERS_EXECUTION, the memory device 100 may still apply the ground voltage (for example, 0 V) or the voltage close to the ground voltage to the first word lines 1st WLs and the second word lines 2nd WLs. For example, after the fourth time point t4, the voltage of the first word lines 1stWLs and the second word lines 2ndWLs may be maintained at the level of the ground voltage (for example, 0 V) or the level of the voltage close to the ground voltage. In the erase execution period ERS_EXECUTION, the memory device 100 may still apply the block word line voltage V_BLKWL at the level higher than the level of the erase voltage V_ERS to the block word line BLKWL. For example, after the fourth time point t4, the block word line BLKWL may be maintained at the level of the block word line voltage V_BLKWL, which is higher than the level of the erase voltage V_ERS.

When the level of the voltage of the common source line CSL increases to a level of a voltage equal to or higher than the GIDL voltage V_GIDL that is the minimum voltage for generating the GIDL in the erase setup period ERS_SET-UP, holes are generated at the source edge of the ground erase control transistor GDT_GS, and accordingly, a channel is charged from the end of the common source line CSL of the cell string CSTR. In the erase execution period ERS_EXECUTION, the level of the voltage of the common source line CSL is maintained as the level of the erase voltage V_ERS, and charging of the channel continues from the end of the common source line CSL.

Through the above operation, the channel of the cell string CSTR may be sequentially boosted to the erase voltage V_ERS in a direction from the common source line CSL toward the bit line BL, and data in the plurality of memory cells MC of the cell string CSTR may be erased.

FIG. 7 is a timing diagram illustrating an erase operation of a memory device 100 according to some implementations. The erase operation according to the timing diagram of FIG. 7 may be performed by the memory device 100 of FIG. 1.

Referring to FIG. 7, a lower GIDL erase operation may be performed during a lower GIDL erase period including an erase setup period ERS_SET-UP and an erase execution period ERS_EXECUTION. For example, the erase operation may be the lower GIDL erase operation for the memory block BLKn of FIG. 5A.

In addition, in FIG. 7, description will be made assuming that a level of a voltage V_BLKWL applied to the block word line BLKWL is lower than a level of an erase voltage V_ERS in the erase execution period ERS_EXECUTION of the lower GIDL erase operation. The example of FIG. 7 corresponds to a modified version of the example of FIG. 6, and hereinafter, differences between the example of FIG. 7 and the example of FIG. 6 will be mainly described; the description provided with respect to FIG. 6 applies to FIG. 7 except where noted otherwise or suggested otherwise by context.

In the erase setup period ERS_SET-UP, the memory device 100 may set a level of a voltage applied to the common source line CSL from a level of a ground voltage (for example, 0 V) or a voltage V_CSL close to the ground voltage to a level of the erase voltage V_ERS.

For example, the memory device 100 may apply the ground voltage (for example, 0 V) or the voltage V_CSL close to the ground voltage to the common source line CSL from the 0th time point t0 to the first time point t1. The memory device 100 may increase the voltage applied to the common source line CSL with a predetermined slope from the first time point t1 to the fourth time point t4. For example, the voltage applied to the common source line CSL at the fourth time point t4 may reach the level of the erase voltage V_ERS. In some implementations, the memory device 100 steps up the voltage applied to the common source line CSL from the first time point t1 to the fourth time point t4, and the voltage applied to the common source line CSL at the fourth time point t4 may reach the level of the erase voltage V_ERS.

In the erase setup period ERS_SET-UP, the memory device 100 may apply a bias voltage V_BLKWL-Vth at a level lower than the level of the voltage V_BLKWL applied to the block word line BLKWL in the erase execution period ERS_EXECUTION to the ground selection line GSL and the lower erase control line GIDL_GS. The voltage Vth may be a threshold voltage of the ground selection transistor GST. After a predetermined time has passed, the memory device 100 may make the ground selection line GSL and the lower erase control line GIDL_GS floating.

Here, the voltage applied to the ground selection line GSL and the lower erase control line GIDL_GS may be coupled to the common source line CSL. For example, a level of the voltage applied to the ground selection line GSL and the lower erase control line GIDL_GS may be coupled to the level of the voltage applied to the common source line CSL and increase.

For example, the memory device 100 may apply the ground voltage (for example, 0 V) or the voltage V_CSL close to the ground voltage to the ground selection line GSL and the lower erase control line GIDL_GS from the 0th time point t0 to the first time point t1. The memory device 100 may apply a bias voltage V_BLKWL-Vth at a level lower than the level of the voltage V_BLKWL applied to the block word line BLKWL in the erase execution period ERS_EXECUTION to the ground selection line GSL and the lower erase control line GIDL_GS from the first time point t1 to the second time point t2. The memory device 100 may make the ground selection line GSL and the lower erase control line GIDL_GS floating from the second time point t2 to the fourth time point t4. At the fourth time point t4, the ground selection line GSL and the lower erase control line GIDL_GS may have a floating voltage at a level at which a GIDL voltage V_GIDL is subtracted from the erase voltage V_ERS. Here, the GIDL voltage V_GIDL is generated by GIDL of the ground erase control transistor GDT_GS, and the ground erase control transistor GDT_GS may intentionally generate the GIDL during the erase operation.

In the erase setup period ERS_SET-UP, the memory device 100 may apply a bias voltage V_DWL to the dummy word line DWL, and may stop applying the bias voltage V_DWL to the dummy word line DWL before the level of the voltage applied to the common source line CSL reaches the level of the erase voltage V_ERS. Thereafter, the memory device 100 may apply the ground voltage (for example, 0 V) or the voltage close to the ground voltage to the dummy word line DWL, and may make the dummy word line DWL floating after a predetermined time has passed. p For example, the memory device 100 may apply the ground voltage (for example, 0 V) or the voltage close to the ground voltage to the dummy word line DWL before the 0th time point t0. The memory device 100 may apply the bias voltage V_DWL to the dummy word line DWL from the 0th time point t0 to the second time point t2. The memory device 100 may apply the ground voltage (for example, 0 V) or the voltage close to the ground voltage to the dummy word line DWL from the second time point t2 to the third time point t3. The memory device 100 may make the dummy word line DWL floating from the third time point t3 to the fourth time point t4. At the fourth time point t4, the dummy word line DWL may have a floating voltage at a level lower than the level at which the GIDL voltage V_GIDL is subtracted from the erase voltage V_ERS.

In the erase setup period ERS_SET-UP, the memory device 100 may apply a bias voltage V_1stWL to the first word lines 1st WLs, and may stop applying the bias voltage V_1stWL to the first word lines 1stWLs before the level of the voltage applied to the common source line CSL reaches the level of the erase voltage V_ERS.

For example, the memory device 100 may apply the ground voltage (for example, 0 V) or the voltage close to the ground voltage to the first word lines 1st WLs before the 0th time point t0. The memory device 100 may apply the bias voltage V_1stWL to the first word lines 1st WLs from the 0th time point t0 to the second time point t2. The memory device 100 may apply the ground voltage (for example, 0 V) or the voltage close to the ground voltage to the dummy word line DWL from the second time point t2 to the fourth time point t4.

In the erase setup period ERS_SET-UP, the memory device 100 may apply the ground voltage (for example, 0 V) or the voltage close to the ground voltage to the second word lines 2nd WLs.

For example, the memory device 100 may apply the ground voltage (for example, 0 V) or the voltage close to the ground voltage to the second word lines 2nd WLs from the 0th time point t0 to the fourth time point t4.

In the erase setup period ERS_SET-UP, the memory device 100 may apply a voltage V_t0 for turning on the plurality of pass transistors TRe_u, TRs, TR1 to TR5, TRd, TRg, and TRe_d of FIG. 5B to the block word line BLKWL. After a predetermined time has passed, the memory device 100 may apply the block word line voltage V_BLKWL at the level lower than the level of the erase voltage V_ERS.

For example, the memory device 100 may apply the ground voltage (for example, 0 V) or the voltage close to the ground voltage to the block word line BLKWL before the 0th time point t0. The memory device 100 may start and stop applying the voltage V_t0 for turning on the plurality of pass transistors TRe_u, TRs, TR1 to TR5, TRd, TRg, and TRe_d of FIG. 5B to the block word line BLKWL from the 0th time point t0 to the first time point t1. Here, when the application of the voltage V_t0 is terminated, the memory device 100 may apply the ground voltage (for example, 0 V) or the voltage close to the ground voltage to the block word line BLKWL until the first time point t1. The memory device 100 may apply the block word line voltage V_BLKWL at the level lower than the level of the erase voltage V_ERS to the block word line BLKWL from the first time point t1 to the fourth time point t4.

In the erase execution period ERS_EXECUTION, the memory device 100 may maintain the level of the voltage applied to the common source line CSL as the level of the erase voltage V_ERS. For example, after the fourth time point t4, the common source line CSL may be maintained at the level of the erase voltage V_ERS. In the erase execution period ERS_EXECUTION, the memory device 100 may still float the dummy word line DWL. For example, after the fourth time point t4, the voltage of the dummy word line DWL may be maintained as the floating voltage at the level lower than the level at which the GIDL voltage V_GIDL is subtracted from the erase voltage V_ERS. In the erase execution period ERS_EXECUTION, the memory device 100 may still apply the ground voltage (for example, 0 V) or the voltage close to the ground voltage to the first word lines 1st WLs and the second word lines 2nd WLs. For example, after the fourth time point t4, the voltage of the first word lines 1stWLs and the second word lines 2ndWLs may be maintained at the level of the ground voltage (for example, 0 V) or the level of the voltage close to the ground voltage. In the erase execution period ERS_EXECUTION, the memory device 100 may still apply the block word line voltage V_BLKWL at the level higher than the level of the erase voltage V_ERS to the block word line BLKWL. For example, after the fourth time point t4, the block word line BLKWL may be maintained at the level of the block word line voltage V_BLKWL, which is higher than the level of the erase voltage V_ERS.

When the level of the voltage of the common source line CSL increases to a level of a voltage equal to or higher than the GIDL voltage V_GIDL that is the minimum voltage for generating the GIDL in the erase setup period ERS_SET-UP, holes are generated at the source edge of the ground erase control transistor GDT_GS, and accordingly, a channel is charged from the end of the common source line CSL of the cell string CSTR. In the erase execution period ERS_EXECUTION, the level of the voltage of the common source line CSL is maintained as the level of the erase voltage V_ERS, and charging of the channel continues from the end of the common source line CSL.

Through the above operation, the channel of the cell string CSTR may be sequentially boosted to the erase voltage V_ERS in a direction from the common source line CSL toward the bit line BL, and data in the plurality of memory cells MC of the cell string CSTR may be erased.

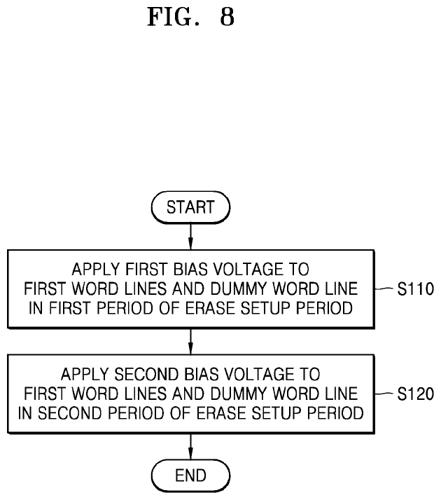

FIG. 8 is a flowchart illustrating an erase method of a memory device 100 according to some implementations. The erasing method of FIG. 8 may be performed by the memory device 100 of FIG. 1, and the erasing method may be applied to the circuits and operations described with respect to FIGS. 1 to 7.

The memory device 100 may include the memory cell array 110 including the plurality of cell strings each extending in the vertical direction on the substrate. Here, each cell string CSTR (refer to FIG. 5B) may include the plurality of memory cells connected to the plurality of word lines, the ground erase control transistor GDT_GS connected to the ground erase control line GIDL_GS, and at least one dummy memory cell DMC connected to the dummy word line DWL. In some implementations, a dummy memory cell DMC is not included (e.g., in the case where the memory block is a memory block of FIGS. 3A-3C), in which case the erase method can be performed by ignoring reference to the dummy word line DWL and voltages applied thereto.

In addition, the ground erase control transistor GDT_GS and the at least one dummy memory cell DMC may be connected between the common source line CSL and the plurality of memory cells.

In addition, the plurality of word lines may include the first word lines 1st WLs connected to the memory cells relatively close to the ground erase control transistor GDT_GS, and the second word lines 2nd WLs connected to the memory cells relatively far from the ground erase control transistor GDT_GS. The first word lines 1st WLs and the second word lines 2nd WLs are described in detail with reference to FIG. 5A.

The memory device 100 may perform an erase operation on the memory cell array 110 by using the row decoder 130 (e.g., a row decoder circuit). At this time, the erase operation may be the lower GIDL erase operation, and the lower GIDL erase operation may be performed during the lower GIDL erase period including the erase setup period ERS_SET-UP and the erase execution period ERS_EXECUTION. The erase setup period ERS_SET-UP may refer to a period in which the level of the voltage applied to the common source line increases to the erase voltage level that is the target voltage level.

Referring to FIG. 8, during the erase operation on the memory cell array 110, the memory device 100 may apply the first bias voltage to the first word lines 1st WLs and the dummy word line DWL in the first period of the erase setup period in operation S110.

Here, the first bias voltage applied to the first word lines 1st WLs may be the bias voltage V_1stWLs described in FIGS. 6 and 7, the first bias voltage applied to the dummy word line DWL may be the bias voltage V_DWL described in FIGS. 6 and 7, and the level of the bias voltage V_1stWLs and the level of the bias voltage V_DWL may be the same. However, the voltage levels are not limited thereto, and the level of the bias voltage V_1stWLs and the level of the bias voltage V_DWL may be different from each other.

In some implementations, the first period corresponds to the period between the first time point t1 and the second time point t2 of FIG. 6. In some implementations, the first period corresponds to the period between the 0th time point t0 and the second time point t2 of FIG. 7. However, the timing is not limited thereto and may be modified in various ways.

In addition, the level of the first bias voltage (the level of the bias voltage V_1stWLs and the level of the bias voltage V_DWL) may be higher than the level of the voltage applied to the common source line CSL at the same time. For example, in FIG. 6, the level of the first bias voltage (the level of the bias voltage V_1stWLs and the level of the bias voltage V_DWL) may be higher than the level of the voltage applied to the common source line CSL from the first time point t1 to the second time point t2. In addition, in FIG. 7, the level of the first bias voltage (the level of the bias voltage V_1stWLs and the level of the bias voltage V_DWL) may be higher than the level of the voltage applied to the common source line CSL from the 0th time point t0 to the second time point t2. For example, the level of the first bias voltage (the level of the bias voltage V_1stWLs and the level of the bias voltage V_DWL) may be higher than the level of the voltage applied to the common source line CSL in the first period.

The memory device 100 may apply the second bias voltage at the level lower than the level of the first bias voltage to the first word lines 1st WLs and the dummy word line DWL in the second period after the first period of the erase setup period in operation S120.

Here, the second bias voltage applied to the first word lines 1st WLs and the dummy word line DWL may be the ground voltage (for example, 0 V) or the voltage close to the ground voltage.

In addition, the second period may correspond to the period between the second time point t2 and the third time point t3 in FIGS. 6 and 7. However, the timing is not limited thereto and may be variously modified.

In some implementations, the number of first word lines 1st WLs may be less than the number of second word lines 2nd WLs. For example, the number of first word lines 1st WLs may be one or two, and the number of second word lines 2nd WLs may be n−1 or n−2. Here, n is a positive integer.

In some implementations, the first period is a period in which the GIDL current is not generated in the ground erase control transistor GDT_GS, and the second period is a period in which the GIDL current is generated in the ground erase control transistor GDT_GS. For example, when the GIDL current is generated in the ground erase control transistor GDT_GS, the first period may end and the second period may start. In addition, the memory device 100 may apply the first bias voltage to the first word lines 1st WLs until the GIDL current is generated in the ground erase control transistor GDT_GS in the first period, and may apply the first bias voltage to the dummy word line DWL until the GIDL current is generated in the ground erase control transistor GDT_GS in the first period.

The GIDL current may be generated by a difference between a gate voltage applied to a gate electrode and a drain voltage applied to a drain. For example, the GIDL current may be generated when the gate voltage of the transistor is lower than the drain voltage of the transistor. For example, the ground erase control transistor GDT_GS may generate holes based on the difference between the level of the voltage applied to the common source line CSL and the level of the gate voltage applied to the ground erase control line GIDL_GS. As the generated holes are received to the channel, the GIDL current is generated and the potential of the channel may be changed. Here, the GIDL current is generated by the GIDL of the ground erase control transistor GDT_GS, and the ground erase control transistor GDT_GS may intentionally generate the GIDL during the erase operation in order to supply holes to a channel.

In some implementations, the second period starts before the level of the voltage applied to the common source line CSL reaches the level of the erase voltage V_ERS. For example, in the erase setup period ERS_SET-UP described in FIGS. 6 and 7, the memory device 100 may apply the bias voltage V_DWL to the dummy word line DWL until the second time point t2, and may apply the ground voltage (for example, 0 V) or the voltage close to the ground voltage to the dummy word line DWL from the second time point t2 before the level of the voltage applied to the common source line CSL reaches the level of the erase voltage V_ERS. In some implementations, in the erase setup period ERS_SET-UP described in FIGS. 6 and 7, the memory device 100 may apply the bias voltage V_1stWL to the first word lines 1st WLs until the second time point t2, and may apply the ground voltage (for example, 0 V) or the voltage close to the ground voltage to the first word lines 1st WLs from the second time point t2 before the level of the voltage applied to the common source line CSL reaches the level of the erase voltage V_ERS.

In some implementations, the memory device 100 may make the dummy word line DWL floating in a third period after the second period. Here, the third period may correspond to the period between the third time point t3 and the fourth time point t4 in FIGS. 6 and 7. However, the timing and voltage application is not limited thereto and may be variously modified.

According to some implementations, by applying the bias voltage at the level higher than the level of the voltage applied to the common source line CSL to the first word lines 1st WLs and the dummy word line DWL connected to the memory cells relatively close to the ground erase control transistor GDT_GS during the erase setup period, it is possible to prevent the HCI phenomenon that may occur before holes are injected into the channel (that is, before the GIDL current is generated) from occurring.

When the HCI phenomenon occurs in the ground erase control transistor GDT_GS, the level of the voltage of the common source line CSL increases, but the channel may be negatively boosted because holes are not injected into the channel.

Furthermore, because the ground erase control transistor GDT_GS is adjacent to the lowermost end of the 3D memory cell array (for example, the substrate SUB including the common source line CSL), concentration of n-type conductive impurities may not be sufficiently controlled during the process. Accordingly, GIDL current generation characteristics of the ground erase control transistor GDT_GS my bae inferior to those of the erase control transistor GDT adjacent to the bit line, and the ground erase control transistor GDT_GS may be vulnerable to the HCI phenomenon.

According to some implementations, by applying the bias voltage at the level higher than the level of the voltage applied to the common source line CSL to the first word lines 1st WLs and the dummy word line DWL connected to memory cells relatively close to the ground erase control transistor GDT_GS during the erase setup period, the HCI phenomenon may be caused in memory cells close to the first word lines 1st WLs among the memory cells connected to the second word lines 2nd WLs so that the HCI phenomenon may not occur in the ground erase control transistor GDT_GS,

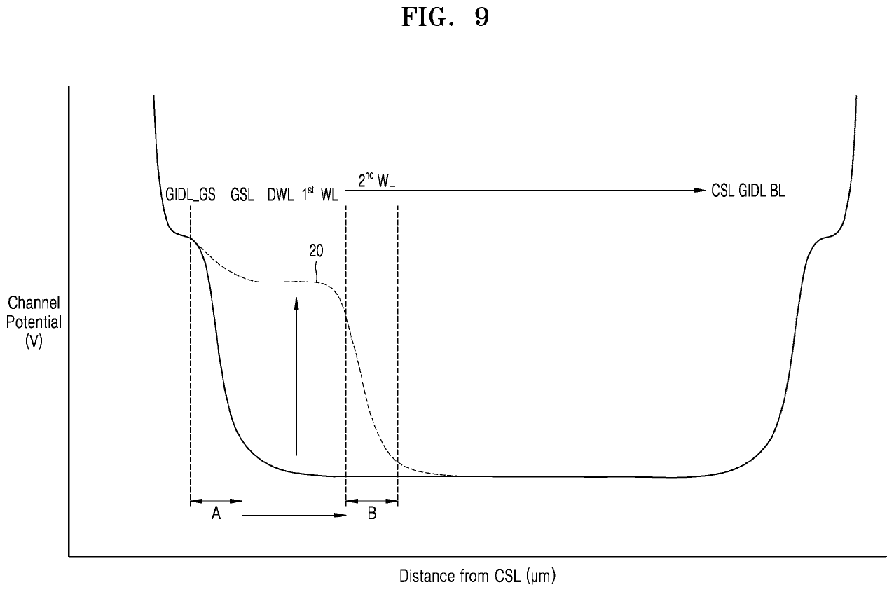

These concepts are described in more detail with reference to FIG. 9.

FIG. 9 is a graph illustrating channel potential for a distance from a common source line CSL according to some implementations. FIG. 9 is a graph schematically illustrating the channel potential for the distance from the common source line CSL at an arbitrary time point between the first time point t1 and the second time point t2 in FIGS. 6 and 7. For example, FIG. 9 may be a graph schematically illustrating the channel potential for the distance from the common source line CSL before holes are injected into the channel (for example, before the GIDL current is generated).

Unlike a 2D memory cell array in which all memory cells are directly connected to a substrate, memory cells of a 3D memory cell array may not be directly connected to a substrate. Accordingly, when the word line is turned off, a down-coupling phenomenon (DCP) in which capacitive-coupling occurs to lower the channel potential may occur. For example, a channel adjacent to a turned-off memory cell may have a voltage level at which a threshold voltage of the memory cell is subtracted from a voltage applied to a gate. Accordingly, the channel potential for the distance from the common source line CSL may have the solid-line graph illustrated in FIG. 9.

Referring to FIG. 9, the potential of a channel adjacent to the ground erase control transistor GDT_GS may be increased by applying the bias voltage at the level higher than the level of the voltage applied to the common source line CSL to the first word lines 1st WLs and the dummy word line DWL connected to memory cells relatively close to the ground erase control transistor GDT_GS during the erase setup period, which may be noted by referring to a change from the solid line illustrated in FIG. 9 to the dotted line 20 illustrated in FIG. 9.

For example, the potential of a channel adjacent to the ground erase control transistor GDT_GS connected to the lower erase control line GIDL_GS, the ground selection transistor GST connected to the ground selection line GSL, the dummy memory cell DMC connected to the dummy word line DWL, and the memory cells connected to the first word lines 1st WLs may increase.

Accordingly, the HCI phenomenon does not occur in the ground erase control transistor GDT_GS, and the memory device 100 may alleviate negative boosting of the ground erase control transistor GDT_GS.

That is, according to some implementations, by applying the bias voltage at the level higher than the level of the voltage applied to the common source line CSL to the first word lines 1st WLs and the dummy word line DWL connected to the memory cells relatively close to the ground erase control transistor GDT_GS during the erase setup period, the potential of the channel adjacent to the ground erase control transistor GDT_GS may be increased before holes are injected into the channel (that is, before the GIDL current is generated), and accordingly, the negative boosting of the ground erase control transistor GDT_GS may be alleviated.

According to some implementations, by applying the bias voltage at the level higher than the level of the voltage applied to the common source line CSL to the first word lines 1st WLs and the dummy word line DWL connected to the memory cells relatively close to the ground erase control transistor GDT_GS during the erase setup period, a point or region at which the channel potential rapidly changes before holes are injected into the channel (that is, the GIDL current is generated) may be moved to the second word lines 2nd WLs. Referring to FIG. 9, it may be noted that the region in which the channel potential rapidly changes is changed from a solid line region A to a dotted line region B.

For example, the point at which the channel potential rapidly changes may be changed from the channel adjacent to the ground erase control transistor GDT_GS to the channel adjacent to the memory cells adjacent to the first word lines 1st WLs among memory cells connected to the second word lines 2nd WLs.

Accordingly, the HCI phenomenon may occur in the memory cells close to the first word lines 1st WLs among the memory cells connected to the second word lines 2nd WLs. A disturb caused by the HCI phenomenon on the memory cells may be removed by the erase operation in the erase execution period ERS_EXECUTION.

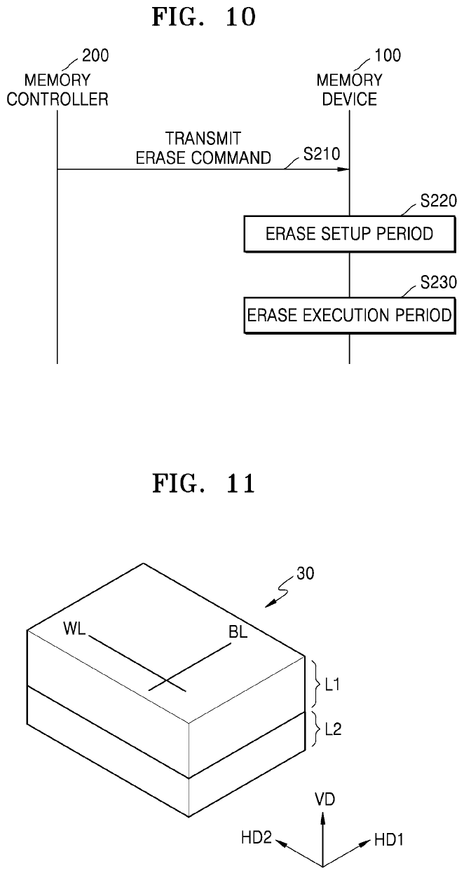

FIG. 10 is a flowchart illustrating an operating method of a memory system. The erasing method of FIG. 10 may be performed by the memory device 100 of FIG. 1, and the erasing method may be applied to the devices and operations described with respect to FIGS. 1 to 9.

Referring to FIG. 10, the memory system may include the memory controller 200 and the memory device 100. The memory controller 200 may transmit an erase command for the memory block to the memory device 100 in operation S210. The memory device 100 may perform a lower GIDL erase operation on the memory block in response to the erase command. At this time, the lower GIDL erase operation may be performed during the lower GIDL erase period including the erase setup period ERS_SET-UP and the erase execution period ERS_EXECUTION. For example, the memory device 100 may perform the method of FIG. 8.

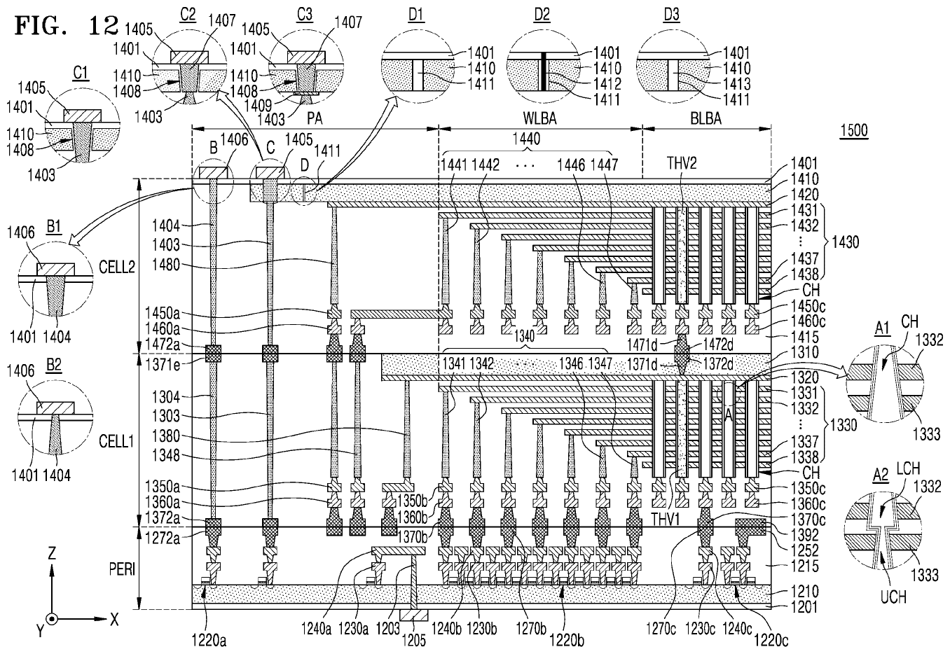

FIG. 11 illustrates a memory device 30 having a cell over peri (COP) structure according to some implementations.

Referring to FIGS. 2 and 11 together, the memory device 30 may include a first semiconductor layer L1 and a second semiconductor layer L2, and the first semiconductor layer L1 may be stacked in the vertical direction VD with respect to the second semiconductor layer L2. For example, the second semiconductor layer L2 may be arranged under the first semiconductor layer L1 in the vertical direction VD. The memory device 100 of FIG. 1 may have the COP structure like the memory device 30.

In some implementations, the memory cell array 110 and the pass transistor circuit 140 may be formed on the first semiconductor layer L1, and the control logic circuit 120, the row decoder 130, the voltage generator 150, and the page buffer circuit 160 may be formed on the second semiconductor layer L2. In some implementations, the memory cell array 110 may be formed on the first semiconductor layer L1, and the pass transistor circuit 140, the control logic circuit 120, the row decoder 130, the voltage generator 150, and the page buffer circuit 160 may be formed on the second semiconductor layer L2. Accordingly, the memory device 30 may have a structure in which the memory cell array 110 is arranged above some peripheral circuits, that is, the COP structure. The COP structure may effectively reduce a horizontal area and may improve integration of the memory device 30.

In some implementations, the second semiconductor layer L2 includes a substrate, and circuits may be formed in the second semiconductor layer L2 by forming semiconductor devices such as transistors and patterns for wiring the devices on the substrate. After the circuits are formed in the second semiconductor layer L2, the first semiconductor layer L1 including the memory cell array 110 may be formed, and patterns for electrically connecting the word lines WL and the bit lines BL of the memory cell array 110 to the circuits formed in the second semiconductor layer L2 may be formed.

FIG. 12 is a cross-sectional view of a memory device 1500 having a BVNAND structure according to some implementations. The memory device 1500 can be, for example, at least a portion of memory device 100.

Referring to FIG. 12, the memory device 1500 may have a chip-to-chip (C2C) structure. Here, the C2C structure may refer to manufacturing at least one upper chip including a cell region CELL and a lower chip including a peripheral circuit region PERI, and then connecting the at least one upper chip to the lower chip by the bonding method. For example, the bonding method may refer to a method of electrically or physically connecting a bonding metal pattern formed on the uppermost metal layer of the upper chip and a bonding metal pattern formed on the uppermost metal layer of the lower chip to each other. For example, when the bonding metal patterns include copper (Cu), the bonding method may be a Cu—Cu bonding method. As another example, the bonding metal patterns may include aluminum (Al) or tungsten (W).

The memory device 1500 may include at least one upper chip including a cell region. For example, as illustrated in FIG. 12, the memory device 1500 may be implemented to include two upper chips, which is only exemplary. The number of upper chips is not limited thereto. When the memory device 1500 includes two upper chips, the memory device 1500 may be manufactured by manufacturing a first upper chip including a first cell region CELL1, a second upper chip including a second cell region CELL2, and a lower chip including a peripheral circuit region PERI, respectively, and then connecting the first upper chip, the second upper chip, and the lower chip to one another by a bonding method. The first upper chip may be inverted and connected to the lower chip by the bonding method, and the second upper chip may also be inverted and connected to the first upper chip by the bonding method. In the following description, upper and lower portions of the first and second upper chips are defined based on the time before the first and second upper chips are inverted. That is, in FIG. 12, the upper portion of the lower chip refers to an upper portion defined based on a +Z axis direction, and the upper portion of each of the first and second upper chips refers to an upper portion defined based on a −Z axis direction, which is only exemplary. Either one of the first upper chip and the second upper chip may be inverted and connected by the bonding method.

Each of the peripheral circuit region PERI and the first and second cell regions CELL1 and CELL2 of the memory device 1500 may include an external pad bonding region PA, a word line bonding region WLBA, and a bit line bonding region BLBA.

The peripheral circuit region PERI may include a first substrate 1210 and a plurality of circuit elements 1220a, 1220b, and 1220c formed on the first substrate 1210. An interlayer insulating layer 1215 including one or more insulating layers may be provided on the plurality of circuit elements 1220a, 1220b, and 1220c, and a plurality of metal wires connecting the plurality of circuit elements 1220a, 1220b, and 1220c may be provided in the interlayer insulating layer 1215. For example, the plurality of metal wires may include first metal wires 1230a, 1230b, and 1230c connected to the plurality of circuit elements 1220a, 1220b, and 1220c, respectively, and second metal wires 1240a, 1240b, and 1240c formed on the first metal wires 1230a, 1230b, and 1230c. The plurality of metal wires may include at least one of various conductive materials. For example, the first metal wires 1230a, 1230b, and 1230c may include W having relatively high electrical resistivity, and the second metal wires 1240a, 1240b, and 1240c may include Cu having relatively low electrical resistivity.

In the current description, only the first metal wires 1230a, 1230b, and 1230c and the second metal wires 1240a, 1240b, and 1240c are illustrated and described, but this disclosure is not limited thereto, and one or more additional metal wires may be further formed on the second metal wires 1240a, 1240b, and 1240c. In this case, the second metal wires 1240a, 1240b, and 1240c may include Al. In addition, at least some of the additional metal wires formed on the second metal wires 1240a, 1240b, and 1240c may include Cu having lower electrical resistivity than Al of the second metal wires 1240a, 1240b, and 1240c.

The interlayer insulating layer 1215 is arranged on the first substrate 1210 and may include an insulating material such as silicon oxide or silicon nitride.

Each of the first and second cell regions CELL1 and CELL2 may include at least one memory block. The first cell region CELL1 may include a second substrate 1310 and a common source line 1320. On the second substrate 1310, a plurality of upper and lower word lines 1331 to 1338 may be stacked in a direction (Z axis direction) perpendicular to a top surface of the second substrate 1310. String selection lines and a ground selection line may be arranged on and under the plurality of upper and lower word lines 1331 to 1338, and the plurality of upper and lower word lines 1331 to 1338 may be arranged between the string selection lines and the ground selection line. Likewise, the second cell region CELL2 includes a third substrate 1410 and a common source line 1420, and a plurality of word lines 1431 to 1438 may be stacked in a direction (Z axis direction) perpendicular to a top surface of the third substrate 1410. The second substrate 1310 and the third substrate 1410 may include various materials and may be, for example, a silicon substrate, a silicon-germanium substrate, a germanium substrate, or a substrate having a single crystal epitaxial layer grown on a monocrystalline silicon substrate. A plurality of channel structures CH may be formed in each of the first and second cell regions CELL1 and CELL2.

In some implementations, as illustrated in A1, the plurality of channel structures CH are provided in a bit line bonding region BLBA and extend in a direction perpendicular to the top surface of the second substrate 1310 through the plurality of upper and lower word lines 1331 to 1338, the string selection lines, and the ground selection line. The channel structure CH may include a data storage layer, a channel layer, and a buried insulating layer. The channel layer may be electrically connected to first metal wires 1350c and second metal wires 1360c in the bit line bonding region BLBA. For example, the second metal wires 1360c may be bit lines, and may be connected to the plurality of channel structures CH through the first metal wires 1350c. The bit line may extend in the first direction (Y axis direction) parallel to the top surface of the second substrate 1310.

In some implementations, as illustrated in A2, the channel structure CH includes a lower channel LCH and an upper channel UCH connected to each other. For example, the channel structure CH may be formed through a process for the lower channel LCH and a process for the upper channel UCH. The lower channel LCH may extend in a direction perpendicular to the top surface of the second substrate 1310 through the common source line 1320 and the lower word lines 1331 and 1332. The lower channel LCH may include a data storage layer, a channel layer, and a buried insulating layer, and may be connected to the upper channel UCH. The upper channel UCH may pass through the upper word lines 1333 to 1338. The upper channel UCH may include a data storage layer, a channel layer, and a buried insulating layer, and the channel layer of the upper channel UCH may be electrically connected to the first metal wire 1350c and the second metal wire 1360c. As a length of a channel increases, it may become difficult to form a channel having a constant width due to process reasons. The memory device 1500 may have a channel with improved width uniformity through the lower channel LCH and the upper channel UCH formed through sequential processes.

As illustrated in A2, when the channel structure CH is formed to include the lower channel LCH and the upper channel UCH, word lines near a boundary between the lower channel LCH and the upper channel UCH may be dummy word lines. For example, the lower word lines 1332 and 1333 forming the boundary between the lower channel LCH and the upper channel UCH may be dummy word lines. In this case, data may not be stored in memory cells connected to the dummy word lines. In some implementations, the number of pages corresponding to the memory cells connected to the dummy word lines may be less than the number of pages corresponding to memory cells connected to general word lines. A level of a voltage applied to the dummy word line may be different from a level of the voltage applied to the general word line, and accordingly, influence of a non-uniform channel width between the lower channel LCH and the upper channel UCH on the operation of the memory device may be reduced.

Meanwhile, in A2, the number of lower word lines 1331 and 1332 through which the lower channel LCH passes is illustrated as being less than the number of upper word lines 1333 and 1338 through which the upper channel UCH passes, which is only exemplary. The number is not limited thereto. As another example, the number of lower word lines through which the lower channel LCH passes may be equal to or greater than the number of upper word lines through which the upper channel UCH passes. In addition, the structure and connection relationship of the channel structure CH arranged in the first cell region CELL0 described above may be equally applied to the channel structure CH arranged in the second cell region CELL2.

In the bit line bonding region BLBA, a first through electrode THV1 may be provided in the first cell region CELL1, and a second through electrode THV2 may be provided in the second cell region CELL2. As illustrated in FIG. 12, the first through electrode THV1 may pass through the common source line 1320 and the plurality of upper and lower word lines 1331 to 1338, which is only exemplary. The first through electrode THV1 may further pass through the second substrate 1310. The first through electrode THV1 may include a conductive material. Alternatively, the first through electrode THV1 may include a conductive material surrounded by an insulating material. The second through electrode THV2 may also be provided in the same shape and structure as the first through electrode THV1.

In some implementations, the first through electrode THV1 and the second through electrode THV2 are electrically connected through a first through metal pattern 1372d and a second through metal pattern 1472d. The first through metal pattern 1372d may be formed at a lower end of a first upper chip including the first cell region CELL1, and the second through metal pattern 1472d may be formed at an upper end of a second upper chip including the second cell region CELL2. The first through electrode THV1 may be electrically connected to the first metal wire 1350c and the second metal wire 1360c. A lower via 1371d may be formed between the first through electrode THV1 and the first through metal pattern 1372d, and an upper via 1471d may be formed between the second through electrode THV2 and the second through metal pattern 1472d. The first through metal pattern 1372d and the second through metal pattern 1472d may be connected by a bonding method.

In addition, in the bit line bonding region BLBA, an upper metal pattern 1252 may be formed on the uppermost metal layer of a peripheral circuit region PERI, and an upper metal pattern 1392 of the same shape as the upper metal pattern 1252 may be formed on the uppermost metal layer of the first cell region CELL1. The upper metal pattern 1392 of the first cell region CELL1 and the upper metal pattern 1252 of the peripheral circuit region PERI may be electrically connected to each other by a bonding method. In the bit line bonding region BLBA, the bit line may be electrically connected to a page buffer included in the peripheral circuit region PERI. For example, some of the circuit elements 1220c of the peripheral circuit region PERI may provide a page buffer, and the bit lines may be electrically connected to the circuit elements 1220c providing the page buffer through upper bonding metals 1370c of the first cell region CELL1 and upper bonding metals 1270c of the peripheral circuit region PERI.

Subsequently, referring to FIG. 12, in the word line bonding region WLBA, the plurality of upper and lower word lines 1331 to 1338 of the first cell region CELL1 may extend in a second direction (X axis direction) parallel to the top surface of the second substrate 1310, and may be connected to a plurality of cell contact plugs 1341 to 1347. First metal wires 1350b and second metal wires 1360b may be sequentially connected to the plurality of cell contact plugs 1341 to 1347 connected to the plurality of upper and lower word lines 1331 to 1338. The plurality of cell contact plugs 1341 to 1347 may be connected to the peripheral circuit region PERI through upper bonding metals 1370b of the first cell region CELL1 and upper bonding metals 1270b of the peripheral circuit region PERI in the word line bonding region WLBA.

The plurality of cell contact plugs 1341 to 1347 may be electrically connected to a row decoder included in the peripheral circuit region PERI. For example, some of the circuit elements 1220b of the peripheral circuit region PERI provide the row decoder, and the plurality of cell contact plugs 1341 to 1347 may be electrically connected to the circuit elements 1220b providing the row decoder through the upper bonding metals 1370b of the first cell region CELL1 and the upper bonding metals 1270b of the peripheral circuit region PERI. In some implementations, an operating voltage of the circuit elements 1220b providing the row decoder is different from an operating voltage of the circuit elements 1220c providing the page buffer. For example, the operating voltage of the circuit elements 1220c providing the page buffer may be greater than the operating voltage of the circuit elements 1220b providing the row decoder.

Likewise, in the word line bonding region WLBA, the plurality of word lines 1431 to 1438 of the second cell region CELL2 may extend in the second direction (X axis direction) parallel to the top surface of the third substrate 1410, and may be connected to a plurality of cell contact plugs 1441 to 1447. The plurality of cell contact plugs 1441 to 1447 may be connected to the peripheral circuit region PERI through the upper metal pattern of the second cell region CELL2, the lower metal pattern and the upper metal pattern of the first cell region CELL1, and a cell contact plug 1348.

In the word line bonding region WLBA, the upper bonding metals 1370b may be formed in the first cell region CELL1, and the upper bonding metals 1270b may be formed in the peripheral circuit region PERI. The upper bonding metals 1370b of the first cell region CELL1 and the upper bonding metals 1270b of the peripheral circuit region PERI may be electrically connected by the bonding method. The upper bonding metal 1370b and the upper bonding metal 1270b may include Al, Cu, or W.

In the external pad bonding region PA, lower metal patterns 1371e may be formed in a lower portion of the first cell region CELL1, and upper metal patterns 1472a may be formed in an upper portion of the second cell region CELL2. The lower metal patterns 1371e of the first cell region CELL1 and the upper metal patterns 1472a of the second cell region CELL2 may be connected by the bonding method in the external pad bonding region PA. Likewise, upper metal patterns 1372a may be formed in an upper portion of the first cell region CELL1, and upper metal patterns 1272a may be formed in an upper portion of the peripheral circuit region PERI. The upper metal patterns 1372a of the first cell region CELL1 and the upper metal patterns 1272a of the peripheral circuit region PERI may be connected by the bonding method.

Common source line contact plugs 1380 and 1480 may be arranged in the external pad bonding region PA. The common source line contact plugs 1380 and 1480 may include a conductive material such as a metal, a metal compound, or doped polysilicon. The common source line contact plug 1380 of the first cell region CELL1 may be electrically connected to the common source line 1320, and the common source line contact plug 1480 of the second cell region CELL2 may be electrically connected to the common source line 1420. A first metal wire 1350a and a second metal wire 1360a may be sequentially stacked on the common source line contact plug 1380 of the first cell region CELL1, and a first metal wire 1450a and a second metal wire 1460a may be sequentially stacked on the common source line contact plug 1480 of the second cell region CELL2.

First to third input/output pads 1205, 1405, and 1406 may be arranged in the external pad bonding region PA. Referring to FIG. 12, a lower insulating layer 1201 may cover a bottom surface of the first substrate 1210, and the first input/output pad 1205 may be formed on the lower insulating layer 1201. The first input/output pad 1205 may be connected to at least one of the plurality of circuit elements 1220a arranged in the peripheral circuit region PERI through a first input/output contact plug 1203, and may be separated from the first substrate 1210 by the lower insulating layer 1201. In addition, a side insulating layer may be arranged between the first input/output contact plug 1203 and the first substrate 1210 to electrically separate the first input/output contact plug 1203 from the first substrate 1210.

An upper insulating layer 1401 covering the top surface of the third substrate 1410 may be formed on the third substrate 1410. The second input/output pad 1405 and/or the third input/output pad 1406 may be arranged on the upper insulating layer 1401. The second input/output pad 1405 may be connected to at least one of the plurality of circuit elements 1220a arranged in the peripheral circuit region PERI through second input/output contact plugs 1403 and 1303, and the third input/output pad 1406 may be connected to at least one of the plurality of circuit elements 1220a arranged in the peripheral circuit region PERI through third input/output contact plugs 1404 and 1304.

In some implementations, the third substrate 1410 is not arranged in a region in which the input/output contact plug is arranged. For example, as illustrated in B, the third input/output contact plug 1404 may be separated from the third substrate 1410 in a direction parallel to the top surface of the third substrate 1410, and may be connected to the third input/output pad 1406 through an interlayer insulating layer 1415 of the second cell region CELL2. In this case, the third input/output contact plug 1404 may be formed by various processes.

For example, as illustrated in B1, the third input/output contact plug 1404 may extend in a third direction (Z axis direction) and may have a diameter increasing toward the upper insulating layer 1401. That is, while a diameter of the channel structure CH described in Al may decrease toward the upper insulating layer 1401, the diameter of the third input/output contact plug 1404 may increase toward the upper insulating layer 1401. For example, the third input/output contact plug 1404 may be formed after the second cell region CELL2 and the first cell region CELL1 are combined by the bonding method.

In addition, for example, as illustrated in B2, the third input/output contact plug 1404 may extend in the third direction (Z axis direction) and may have a diameter decreasing toward the upper insulating layer 1401. That is, the diameter of the third input/output contact plug 1404 may decrease toward the upper insulating layer 1401 like the diameter of the channel structure CH. For example, the third input/output contact plug 1404 may be formed together with the plurality of cell contact plugs 1441 to 1447 before the second cell region CELL2 and the first cell region CELL1 are combined by the bonding method.

In some implementations, the input/output contact plug may be arranged to overlap the third substrate 1410. For example, as illustrated in C, the second input/output contact plug 1403 is formed through the interlayer insulating layer 1415 of the second cell region CELL2 in the third direction (Z axis direction), and may be electrically connected to the second input/output pad 1405 through the third substrate 1410. In this case, a connection structure between the second input/output contact plug 1403 and the second input/output pad 1405 may be implemented in various ways.

For example, as illustrated in C1, an opening 1408 may be formed through the third substrate 1410, and the second input/output contact plug 1403 may be directly connected to the second input/output pad 1405 through the opening 1408 formed in the third substrate 1410. In this case, as illustrated in C1, a diameter of the second input/output contact plug 1403 may increase toward the second input/output pad 1405, which is only exemplary. The diameter of the second input/output contact plug 1403 may decrease toward the second input/output pad 1405.

For example, as illustrated in C2, the opening 1408 may be formed through the third substrate 1410, and a contact 1407 may be formed in the opening 1408. One end of the contact 1407 may be connected to the second input/output pad 1405 and the other end of the contact 1407 may be connected to the second input/output contact plug 1403. Accordingly, the second input/output contact plug 1403 may be electrically connected to the second input/output pad 1405 through the contact 1407 in the opening 1408. In this case, as illustrated in C2, a diameter of the contact 1407 may increase toward the second input/output pad 1405 and the diameter of the second input/output contact plug 1403 may decrease toward the second input/output pad 1405. For example, the second input/output contact plug 1403 may be formed together with the plurality of cell contact plugs 1441 to 1447 before the second cell region CELL2 and the first cell region CELL1 are combined by the bonding method, and the contact 1407 may be formed after the second cell region CELL2 and the first cell region CELL1 are combined by the bonding method.

In addition, for example, as illustrated in C3, a stopper 1409 may be further formed on a top surface of the opening 1408 of the third substrate 1410 compared to C2. The stopper 1409 may be a metal wire formed on the same layer as the common source line 1420, which is only exemplary. The stopper 1409 may be a metal wire formed in the same layer as at least one of the plurality of word lines 1431 to 1438. The second input/output contact plug 1403 may be electrically connected to the second input/output pad 1405 through the contact 1407 and the stopper 1409.

Meanwhile, like the second and third input/output contact plugs 1403 and 1404 of the second cell region CELL2, the second and third input/output contact plugs 1303 and 1304 of the first cell region CELL1 may each have a diameter decreasing or increasing toward the lower metal patterns 1371e.

A slit 1411 may be formed in the third substrate 1410. For example, the slit 1411 may be formed at an arbitrary position in the external pad bonding region PA. For example, as illustrated in D, the slit 1411 may be positioned between the second input/output pad 1405 and the plurality of cell contact plugs 1441 to 1447 when viewed in a plan view, which is only exemplary. When viewed in a plan view, the slit 1411 may be formed so that the second input/output pad 1405 is positioned between the slit 1411 and the plurality of cell contact plugs 1441 to 1447.

For example, as illustrated in D1, the slit 1411 may be formed through the third substrate 1410. For example, the slit 1411 may be used to prevent the third substrate 1410 from being finely cracked when forming the opening 1408, which is only exemplary. The slit 1411 may be formed to a depth of about 60% to 70% of a thickness of the third substrate 1410.

In addition, for example, as illustrated in D2, a conductive material 1412 may be formed in the slit 1411. The conductive material 1412 may be used, for example, to discharge a leakage current generated while driving circuit elements in the external pad bonding region PA. In this case, the conductive material 1412 may be connected to an external ground line.

In addition, for example, as illustrated in D3, an insulating material 1413 may be formed in the slit 1411. The insulating material 1413 may be formed, for example, to electrically separate the second input/output pad 1405 and the second input/output contact plug 1403 arranged in the external pad bonding region PA from the word line bonding region WLBA. By forming the insulating material 1413 in the slit 1411, it is possible to prevent a voltage provided through the second input/output pad 1405 from affecting a metal layer arranged on the third substrate 1410 in the word line bonding region WLBA.

According to some implementations, the first to third input/output pads 1205, 1405, and 1406 may be selectively formed. For example, the memory device 1500 may include only the first input/output pad 1205 arranged on the first substrate 1210, only the second input/output pad 1405 arranged on the third substrate 1410, or only the third input/output pad 1406 arranged on the upper insulating layer 1401.

According to some implementations, at least one of the second substrate 1310 of the first cell region CELL1 and the third substrate 1410 of the second cell region CELL2 may be used as a sacrificial substrate, and may be completely or partially removed before or after the bonding process. An additional layer may be stacked after the substrate is removed. For example, the second substrate 1310 of the first cell region CELL1 may be removed before or after bonding the peripheral circuit region PERI and the first cell region CELL1, and an insulating layer covering a top surface of the common source line 1320 or a conductive layer for connection may be formed. Similarly, the third substrate 1410 of the second cell region CELL2 may be removed before or after bonding the first cell region CELL1 and the second cell region CELL2, and the upper insulating layer 1401 covering a top surface of the common source line 1420 or a conductive layer for connection may be formed.

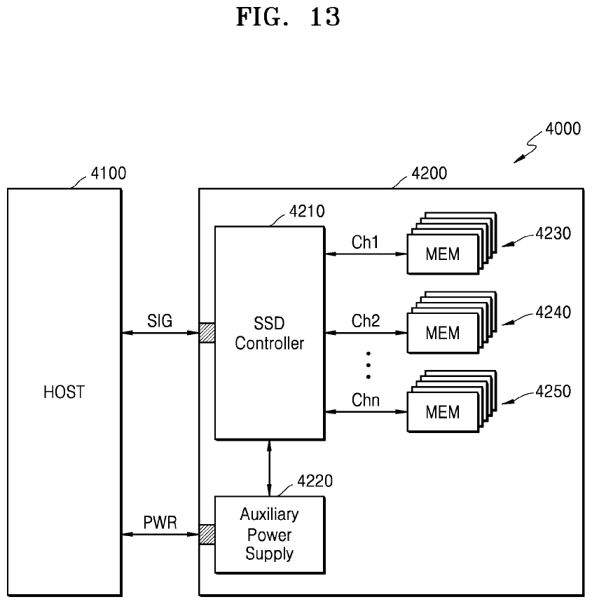

FIG. 13 is a block diagram illustrating an example in which a memory device (e.g., memory device 100) is applied to a solid state drive (SSD) system 4000.

Referring to FIG. 13, the SSD system 4000 may include a host 4100 and an SSD 4200. The SSD 4200 transmits and receives signals to and from the host 4100 through a signal connector and receives power through a power connector. The SSD 4200 may include an SSD controller 4210, an auxiliary power supply 4220, and memory devices 4230, 4240, and 4250. The memory devices 4230, 4240 and 4250 may be vertically stacked NAND flash memory devices. At this time, the memory devices 4230, 4240, and 4250 may be implemented using the memory devices and operations described above with reference to FIGS. 1 to 12.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While various examples have been particularly shown and described, it will be understood that various changes in form and details may be made therein without departing from the spirit and scope of this disclosure.

What is claimed is:

1. A memory device comprising:
a memory cell array including a plurality of cell strings each extending in a vertical direction on a substrate; and
a row decoder,
wherein each cell string of the plurality of cell strings comprises
a plurality of memory cells respectively connected to a plurality of word lines,
a ground erase control transistor connected to a ground erase control line, and
at least one dummy memory cell connected to a dummy word line,
wherein the ground erase control transistor and the at least one dummy memory cell are connected between a common source line and the plurality of memory cells, and
wherein the plurality of word lines comprise first word lines and second word lines, wherein the first word lines are connected to memory cells that are closer to the ground erase control transistor than are memory cells to which the second word lines are connected; and
wherein the row decoder is configured to apply, during an erase operation on the memory cell array, (i) a first bias voltage to the first word lines and the dummy word line in a first period of an erase setup period, and (ii) a second bias voltage, at a level lower than a level of the first bias voltage, to the first word lines and the dummy word line in a second period, after the first period, of the erase setup period,
wherein the erase setup period comprises a period in which a level of a voltage applied to the common source line increases to an erase voltage level that is a target voltage level, and
wherein the second period starts before the level of the voltage applied to the common source line reaches the erase voltage level.

2. The memory device of claim 1, wherein a level of the first bias voltage is higher than a level of the voltage applied to the common source line in the first period.

3. The memory device of claim 1, wherein a number of the first word lines is less than a number of the second word lines.

4. The memory device of claim 1, wherein the dummy word line is floating in a third period after the second period.

5. The memory device of claim 1, wherein the first period ends and the second period starts at a time at which a gate induced drain leakage current is generated in the ground erase control transistor.

6. The memory device of claim 1, wherein the row decoder is configured to apply the first bias voltage to the first word lines until a gate induced drain leakage current is generated in the ground erase control transistor.

7. The memory device of claim 1, wherein the row decoder is configured to apply the first bias voltage to the dummy word line until a gate induced drain leakage current is generated in the ground erase control transistor.

8. A memory system comprising:
a memory controller; and
a memory device configured to perform an erase operation in response to an erase command received from the memory controller, wherein the memory device comprises:
a memory cell array including a plurality of cell strings each extending in a vertical direction on a substrate, and
a row decoder,
wherein each cell string of the plurality of cell strings comprises:
a plurality of memory cells respectively connected to a plurality of word lines,
a ground erase control transistor connected to a ground erase control line, and
at least one dummy memory cell connected to a dummy word line,
wherein the ground erase control transistor and the at least one dummy memory cell are connected between a common source line and the plurality of memory cells, and
wherein the plurality of word lines comprise first word lines and second word lines, wherein the first word lines are connected to memory cells that are closer to the ground erase control transistor than are memory cells to which the second word lines are connected; and
wherein the row decoder is configured to apply, during an erase operation on the memory cell array, (i) a first bias voltage to the first word lines and the dummy word line in a first period of an erase setup period, and (ii) a second bias voltage, at a level lower than a level of the first bias voltage, to the first word lines and the dummy word line in a second period, after the first period, of the erase setup period,
wherein the erase setup period comprises a period in which a level of a voltage applied to the common source line increases to an erase voltage level that is a target voltage level, and
wherein the second period starts before the level of the voltage applied to the common source line reaches the erase voltage level.

9. The memory system of claim 8, wherein a level of the first bias voltage is higher than a level of the voltage applied to the common source line in the first period.

10. The memory system of claim 8, wherein a number of the first word lines is less than a number of the second word lines.

11. The memory system of claim 8, wherein the dummy word line is floating in a third period after the second period.

12. The memory system of claim 8, wherein the first period ends and the second period starts at a time at which a gate induced drain leakage current is generated in the ground erase control transistor.

13. The memory system of claim 8, wherein the row decoder is configured to apply the first bias voltage to the first word lines until a gate induced drain leakage current is generated in the ground erase control transistor.

14. The memory system of claim 8, wherein the row decoder is configured to apply the first bias voltage to the dummy word line until a gate induced drain leakage current is generated in the ground erase control transistor.

15. An erasing method for a memory device,
wherein the memory device comprises a memory cell array including a plurality of cell strings each extending in a vertical direction on a substrate, wherein each cell string of the plurality of cell strings comprises
a plurality of memory cells respectively connected to a plurality of word lines,
a ground erase control transistor connected to a ground erase control line, and
at least one dummy memory cell connected to a dummy word line,
wherein the ground erase control transistor and the at least one dummy memory cell are connected between a common source line and the plurality of memory cells, and
wherein the plurality of word lines comprise first word lines and second word lines, wherein the first word lines are connected to memory cells that are closer to the ground erase control transistor than are memory cells to which the second word lines are connected, and
wherein the erasing method comprises:
applying a first bias voltage to the first word lines and the dummy word line in a first period of an erase setup period; and
applying a second bias voltage, at a level lower than a level of the first bias voltage, to the first word lines and the dummy word line in a second period. after the first period, of the erase setup period,
wherein the erase setup period comprises a period in which a level of a voltage applied to the common source line increases to an erase voltage level that is a target voltage level, and
wherein the second period starts before the level of the voltage applied to the common source line reaches the erase voltage level.

16. The erasing method of claim 15, wherein a level of the first bias voltage is higher than a level of the voltage applied to the common source line in the first period.

17. The erasing method of claim 15, wherein a number of the first word lines is less than a number of the second word lines.

18. The erasing method of claim 15, further comprising causing the dummy word line to be floating in a third period after the second period.

19. The erasing method of claim 15, wherein the first period ends and the second period starts at a time at which a gate induced drain leakage current is generated in the ground erase control transistor.

20. The erasing method of claim 15, wherein applying the first bias voltage to the first word lines and the dummy word line comprises applying the first bias voltage to the first word lines until a gate induced drain leakage current is generated in the ground erase control transistor.
